(19) United States
(12) Patent Application Publication
(10) Pub. No.: US 2025/0051177 A1
(43) Pub. Date: Feb. 13, 2025

(54) ELECTRON TRANSPORT COMPOSITION, LIGHT-EMITTING ELEMENT MANUFACTURED USING THE SAME, AND METHOD FOR MANUFACTURING THE LIGHT-EMITTING ELEMENT

(71) Applicant: Samsung Display Co., Ltd., Yongin-si (KR)

(72) Inventors: Jungho JO, Yongin-si (KR); SEHUN KIM, Yongin-si (KR); WON-JUN PARK, Yongin-si (KR); CHUL SOON PARK, Yongin-si (KR); JONGWOO SHIN, Yongin-si (KR); Chungman YU, Yongin-si (KR)

(21) Appl. No.: 18/652,634

(22) Filed: May 1, 2024

(30) Foreign Application Priority Data
Aug. 8, 2023 (KR) 10-2023-0103741

(51) Int. Cl. C01G 19/02; H10K 50/115; H10K 50/16; H10K 85/40

(52) U.S. Cl. CPC C01G 19/02; H10K 85/40; C01P 2006/40; H10K 50/115; H10K 50/16

(57) ABSTRACT

An electronic transport composition including inorganic particles (each) represented by Formula 1, and a solvent represented by Formula 2, and when the electron transport composition is applied to a light-emitting element, luminous efficiency characteristics and element lifespan characteristics may be improved.

Zn₁₋ₓMₓO Formula 1

R₁—O—(R₂—O)ₙ—R₃ Formula 2

### CROSS-REFERENCE TO RELATED APPLICATIONS

The present application claims priority to and the benefit of Korean Patent Application No. 10-2023-0103741, filed on Aug. 8, 2023, in the Korean Intellectual Property Office, the entire content of which is incorporated herein by reference.

### BACKGROUND

### 1. Field

Embodiments of the present disclosure described herein are related to an electron transport composition, a light-emitting element manufactured utilizing the same, and a method for manufacturing the light-emitting element.

### 2. Description of the Related Art

Various types (kinds) of display devices utilized for multimedia apparatuses such as a television, a mobile phone, a tablet computer, a navigation system, and a game console are being developed. In such display devices, a so-called self-luminescent display element is utilized, which achieves display by causing a light-emitting material containing an organic compound to emit light.

In some embodiments, the development of a light-emitting element utilizing quantum dots as a light-emitting material has been underway or pursued in order to enhance the color reproducibility of display devices, and there is a demand or desire for improvements in luminous efficiency and/or lifespan of the light-emitting element utilizing such quantum dots.

### SUMMARY

Aspects according to one or more embodiments of the present disclosure are directed toward an electron transport composition containing zinc tin oxide, and a light-emitting element including an electron transport region formed of the electron transport composition to thereby have improved luminous efficiency and/or lifespan.

Aspects according to one or more embodiments of the present disclosure are directed toward a method for manufacturing the light-emitting element, the method including forming of an electron transport region by which the efficiency of a solution process is improved.

Additional aspects will be set forth in part in the description which follows and, in part, will be apparent from the description, or may be learned by practice of the presented embodiments of the present disclosure.

According to one or more embodiments, an electron transport composition that contains inorganic particles (each) may be represented by Formula 1, and a solvent represented by Formula 2.

Zn₁₋ₓMₓO Formula 1

where, in Formula 1 above, M is Sn, Cu, or Ni, and x satisfies 0<x<1.

R₁—O—(R₂—O)ₙ—R₃ Formula 2

where, in Formula 2 above, R₁ is a hydrogen atom, or a deuterium atom, R₂ is a substituted or unsubstituted alkylene group having 1 to 60 carbon atoms, a substituted or unsubstituted cycloalkylene group having 3 to 10 ring-forming carbon atoms, a substituted or unsubstituted heterocycloalkylene group having 2 to 10 ring-forming carbon atoms, a substituted or unsubstituted arylene group having 6 to 30 ring-forming carbon atoms, or a substituted or unsubstituted heteroarylene group having 2 to 30 ring-forming carbon atoms, R₃ is a substituted or unsubstituted alkyl group having 1 to 20 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms, and n is an integer of 1 to 5.

In an embodiment, M may be Sn.

In an embodiment, x may satisfy 0<x<0.2.

In an embodiment, the solvent represented by Formula 2 above may be represented by any one selected from among Formulas 3-1 to 3-3.

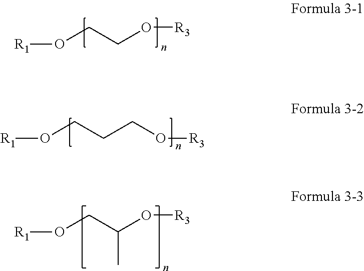

where, in Formulas 3-1 to 3-3, the same descriptions as in Formula 2 above may be applied to R₁, R₃, and n.

In an embodiment, a boiling point of the solvent may be about 200° C. or more.

In an embodiment, the solvent may have a viscosity of about 30 centipoise (cP or cp) or less and a surface tension of about 40 dyne per centimeter (dyn/cm) or less.

In an embodiment, the solvent may have a viscosity of about 20 cp or less, and may have a surface tension of about 34 dyn/cm or less.

In an embodiment, the solvent represented by Formula 2 above may be represented by any one selected from among Formulas 4-1 to 4-8.

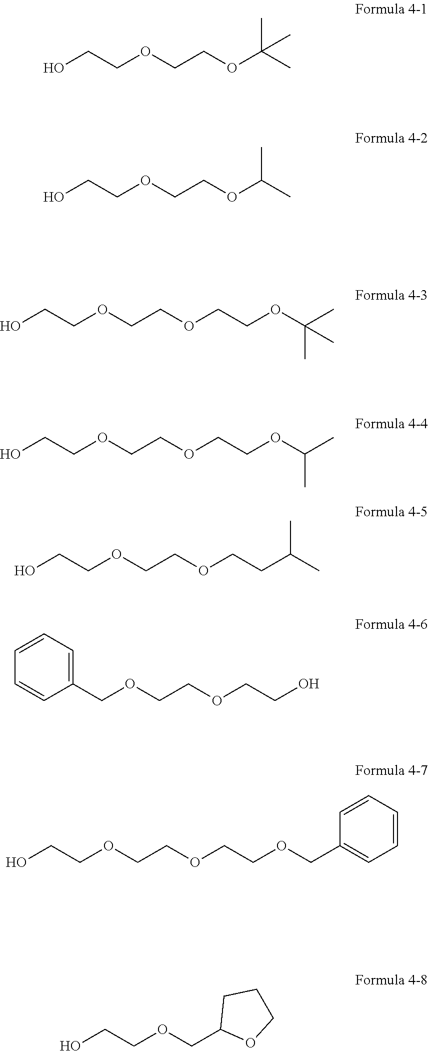

In an embodiment, an additive represented by Formula 5 may be further included.

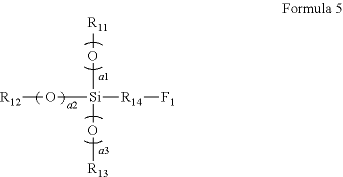

where, in Formula 5 above, R₁₁ to R₁₃ may each independently be a substituted or unsubstituted alkyl group having 1 to 30 carbon atoms, a substituted or unsubstituted cycloalkyl group having 3 to 20 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms, R₁₄ may be a substituted or unsubstituted alkylene group having 1 to 30 carbon atoms, a substituted or unsubstituted cycloalkylene group having 3 to 20 ring-forming carbon atoms, a substituted or unsubstituted arylene group having 6 to 30 ring-forming carbon atoms, or a substituted or unsubstituted heteroarylene group having 2 to 30 ring-forming carbon atoms, a1 to a3 may each independently be 0 or 1, at least one selected from among a1 to a3 may be 1, and F₁ may be a substituted or unsubstituted (meth)acylate group, or a substituted or unsubstituted epoxy group, or a substituted or unsubstituted amine group.

In an embodiment, the additive represented by Formula 5 above may be represented by any one selected from among Formulas 6-1 to 6-5.

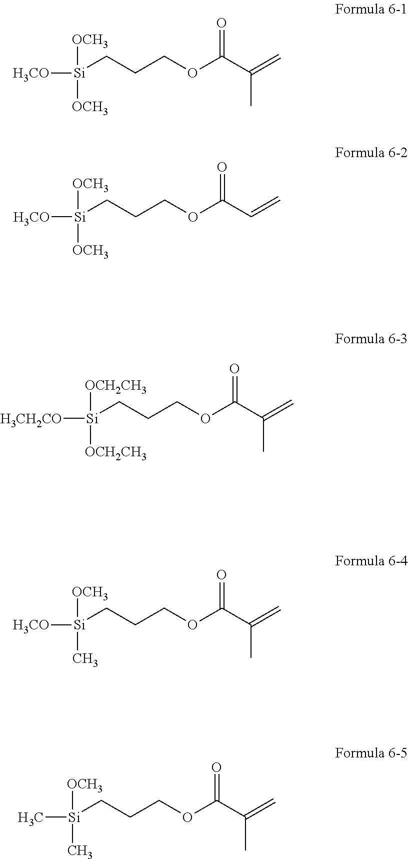

In an embodiment of the present disclosure, a method for manufacturing a light-emitting element according to an embodiment of the present disclosure includes: forming a hole transport region on a first electrode; forming an emission layer on the hole transport region; forming an electron transport region on the emission layer; and forming a second electrode on the electron transport region, wherein the forming of the electron transport region includes: preparing an electron transport composition containing inorganic particles and a solvent; forming a preliminary electron transport region by applying the electron transport composition onto the emission layer; and performing a heat treatment for the preliminary electron transport region at a first temperature, the inorganic particle is represented by Formula 1, and the solvent is represented by Formula 2.

In an embodiment, the first temperature may be about 50° C. to about 150° C.

In an embodiment, the electron transport composition may include about 0.1 wt % to about 5.0 wt % of inorganic particles with respect to 100 wt % of the solvent.

In an embodiment of the present disclosure, a light-emitting element includes a first electrode, a hole transport region disposed on the first electrode, an emission layer disposed on the hole transport region, an electron transport region disposed on the emission layer, and a second electrode disposed on the electron transport region, wherein the electron transport region includes inorganic particles (each) represented by Formula 1.

Zn₁₋ₓMₓO Formula 1

where, in Formula 1 above, M is Sn, Cu, or Ni, and x satisfies 0<x<0.2.

In an embodiment, the emission layer may include quantum dots.
In an embodiment, the quantum dots may include a core and a shell around (e.g., surrounding) the core.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of an electronic apparatus according to an embodiment of the present disclosure;

FIG. 2 is an exploded perspective view of an electronic apparatus according to an embodiment of the present disclosure;

FIG. 3 is a cross-sectional view of an electronic apparatus according to an embodiment of the present disclosure, taken along the line I-I′ in FIG. 2;

FIG. 4 is a plan view illustrating a display device according to an embodiment of the present disclosure;

FIG. 5 is a cross-sectional view of a display device according to an embodiment of the present disclosure;

FIGS. 6-9 are cross-sectional views of a light-emitting element according to an embodiment of the present disclosure;

FIG. 10 is a flow chart showing a method for manufacturing a light-emitting element according to an embodiment;

FIG. 11 is a flow chart that breaks down operations for forming an electron transport region according to an embodiment;

FIG. 12 is a view schematically illustrating an electron transport composition according to an embodiment; and

FIGS. 13 and 14 are views schematically showing some operations for manufacturing a light-emitting element according to an embodiment.

### DETAILED DESCRIPTION

In the present disclosure, one or more suitable modifications may be made, and one or more suitable forms may be applied, and specific embodiments will be illustrated in the drawings and described in more detail in the text. However, this is not intended to limit the present disclosure to a specific disclosure form, and it should be understood to include all changes, equivalents, and substitutes included in the spirit and scope of the present disclosure.

In this specification, when a component (or region, layer, portion, etc.) is referred to as “on”, “connected”, or “coupled” to another component, it refers to that a component (or region, layer, portion, etc.) is directly placed/connected/coupled on the other component or a third component can be disposed between them.

In contrast, as utilized herein, when an element is referred to as being “directly disposed”, there are no intervening layers, membranes, regions, or plates present between a portion such as a layer, a membrane, a region, and a plate and another component. For example, “directly disposed on” may refer to that two layers or two members are directly disposed without utilizing an additional intervening member, such as an adhesive member.

The same reference numerals or symbols refer to the same elements. In some embodiments, in the drawings, thicknesses, ratios, and dimensions of components are exaggerated for an effective description of technical content (e.g., amount). “And/or” includes all combinations of one or more that the associated elements may define.

Terms such as first and second may be utilized to describe one or more suitable components, but the components should not be limited by the terms. These terms are only utilized for the purpose of distinguishing one component from other components. For example, without departing from the scope of the present disclosure, a first component may be referred to as a second component, and similarly, the second component may be referred to as the first component. Singular expressions include plural expressions unless the context clearly indicates otherwise.

In some embodiments, terms such as “below”, “lower”, “above”, and “upper” are utilized to describe the relationship between components shown in the drawings. The terms are relative concepts and are described based on the directions indicated in the drawings.

Unless otherwise defined, all terms (including technical and scientific terms) utilized in this specification have the same meaning as commonly understood by one of ordinary skill in the art to which this present disclosure belongs. In some embodiments, terms such as terms defined in commonly utilized dictionaries should be interpreted as having a meaning consistent with the meaning having In the context of the related technology and should not be interpreted as too ideal or too formal unless explicitly defined here.

Terms such as “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

Hereinafter, an electron transport layer composition according to an embodiment of the present disclosure and a light-emitting element utilizing the same, and a method for manufacturing the light-emitting element will be described in more detail with reference to the accompanying drawings.

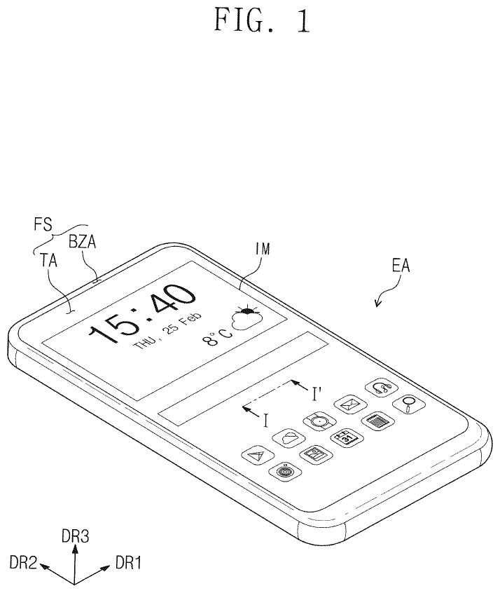

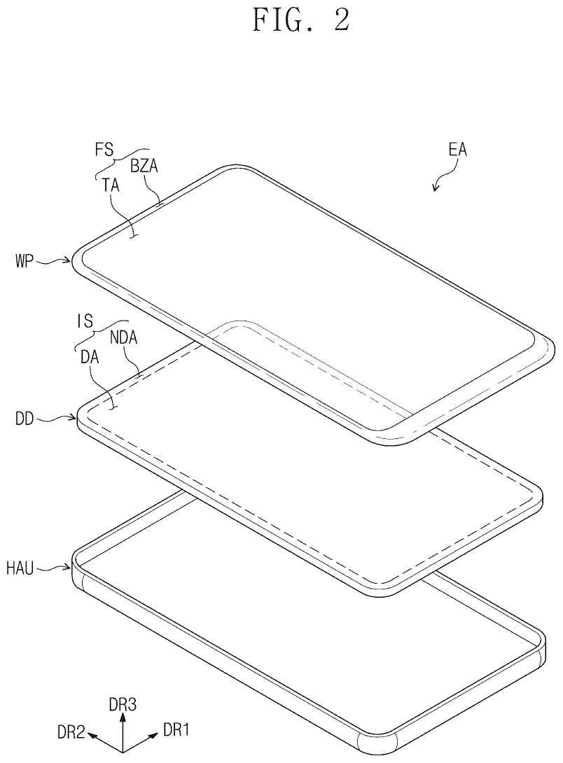

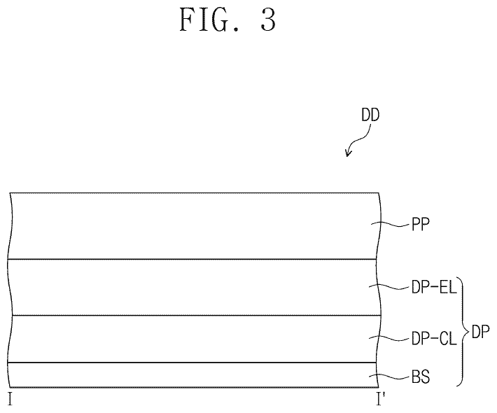

FIG. 1 is a perspective view illustrating an electronic apparatus EA according to an embodiment. FIG. 2 is an exploded perspective view of the electronic apparatus EA according to an embodiment. FIG. 3 is a cross-sectional view of a display device DD according to an embodiment of the present disclosure, taken along the line I-I′ in FIG. 2.

In an embodiment, the electronic apparatus EA may be a large-sized electronic apparatus such as a television, a monitor, or an outdoor billboard. In some embodiments, the electronic apparatus EA may be a medium or small-sized electronic apparatus such as a personal computer, a laptop computer, a personal digital device, a car navigation unit, a game console, a smartphone, a tablet, and a camera. In some embodiments, such devices are suggested as examples only, but other devices may be also utilized as long as they fall within the scope of the present disclosure. In the present embodiment, as an example, a smartphone is shown as the electronic apparatus EA.

The electronic apparatus EA may include a display device DD and a housing HAU. The display device DD may display an image IM through a display surface IS. In FIG. 1, the display surface IS is illustrated to be parallel to a surface defined by a first direction DR1 and a second direction DR2 crossing the first direction DR1. However, this is presented as an example, and in another embodiment, the display surface IS of the display device DD may have a curved shape.

A normal (e.g., perpendicular) direction of the display surface IS, that is, the direction that the image IM is displayed among thickness directions of the display device DD, is indicated by a third direction DR3. A front surface (or top surface) and a rear surface (or bottom surface) of each member may be separated by the third direction DR3.

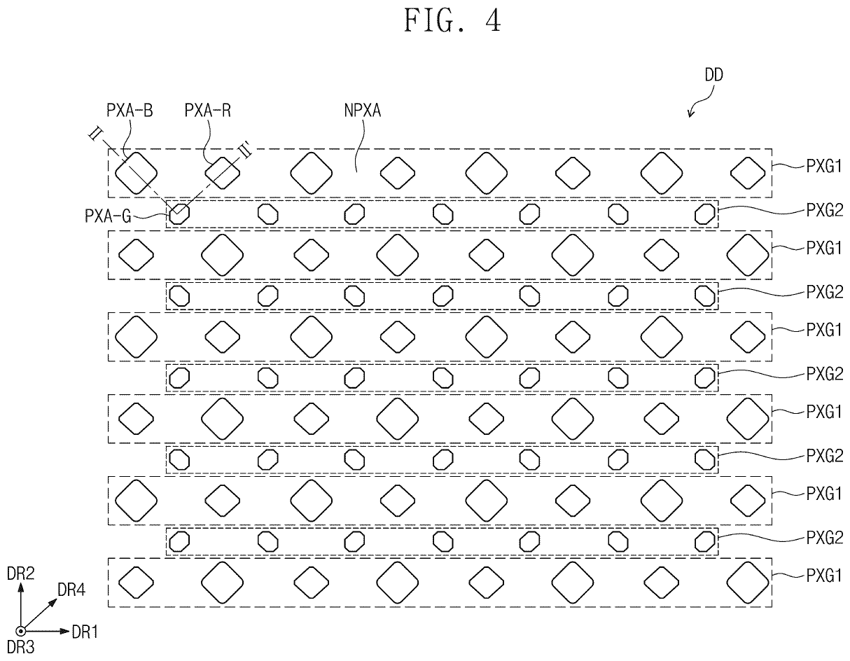

A fourth direction DR4 (see FIG. 4) may be a direction between the first direction DR1 and the second direction DR2. The fourth direction DR4 may be disposed on a surface parallel to the surface defined by the first direction DR1 and the second direction DR2. In some embodiments, the directions indicated by the first to fourth directions DR1, DR2, DR3, and DR4 are relative concepts, and may thus be changed to other directions.

A display surface FS that an image IM is displayed in the electronic apparatus EA may correspond to a front surface of the display device DD and correspond to a front surface of a window WP. Hereinafter, like reference numerals will be given for the display surface and the front surface of the electronic apparatus EA, and the front surface of the window WP. The image IM may include not only an active image but also a still image. In some embodiments, the electronic apparatus EA may include a foldable display device including a folding region and a non-folding region, or a bending display device including at least one bending part.

The housing HAU may accommodate the display device DD. The housing HAU may be disposed to cover the display device DD to expose a top surface, which is the display surface IS of the display device DD. The housing HAU may expose an entire top surface while covering side surfaces and a bottom surface of the display device DD. However, an embodiment of the present disclosure is not limited thereto, and the housing HAU may cover a portion of the top surface as well as the side surfaces and the bottom surface of the display device DD.

In the electronic apparatus EA according to an embodiment, the window WP may include an optically transparent insulating material. The window WP may include a transmission region TA and a bezel region BZA. A front surface FS of the window WP including the transmission layer TA and the bezel region BZA corresponds to a front surface FS of the electronic apparatus EA. A user may view an image provided through the transmission region TA corresponding to the front surface FS of the electronic apparatus EA.

In FIGS. 1 and 2, the transmission region TA is shown to have a rounded rectangular shape with rounded corners. However, this is presented as an example, and the transmission region TA may have one or more suitable shapes, and is not limited to any one embodiment.

The transmission region TA may be optically transparent. The bezel region BZA may be a region having a relatively low optical transmittance. The bezel region BZA may have a set or predetermined color. The bezel region BZA may be adjacent to the transmission region TA and around a (e.g., surrounding) transmission region TA. The bezel region BZA may define a shape of the transmission region TA. However, an embodiment is not limited thereto, the bezel region BZA may be disposed adjacent to at least one side or only one side of the transmission region TA, and a portion thereof may not be provided.

The display device DD may be disposed below the window WP. As utilized herein, “below” may indicate an opposite direction to the direction in which the display device DD provides an image.

In an embodiment, the display device DD may be substantially configured to generate an image IM. The image IM generated in the display device DD is displayed on the display surface IS and is viewed by the user from the outside through the transmission region TA. The display device DD includes a display region DA and a non-display region NDA. A display region DA may be activated in response to an electrical signal. The non-display region NDA may be covered by the bezel region BZA. The non-display region NDA is adjacent to the display region DA. The non-display region NDA may surround the display region DA.

The display device DD may include a display panel DP and an optical member PP disposed on the display panel DP. The display panel DP may include a display element layer DP-EL. The display element layer DP-EL includes a light-emitting element ED.

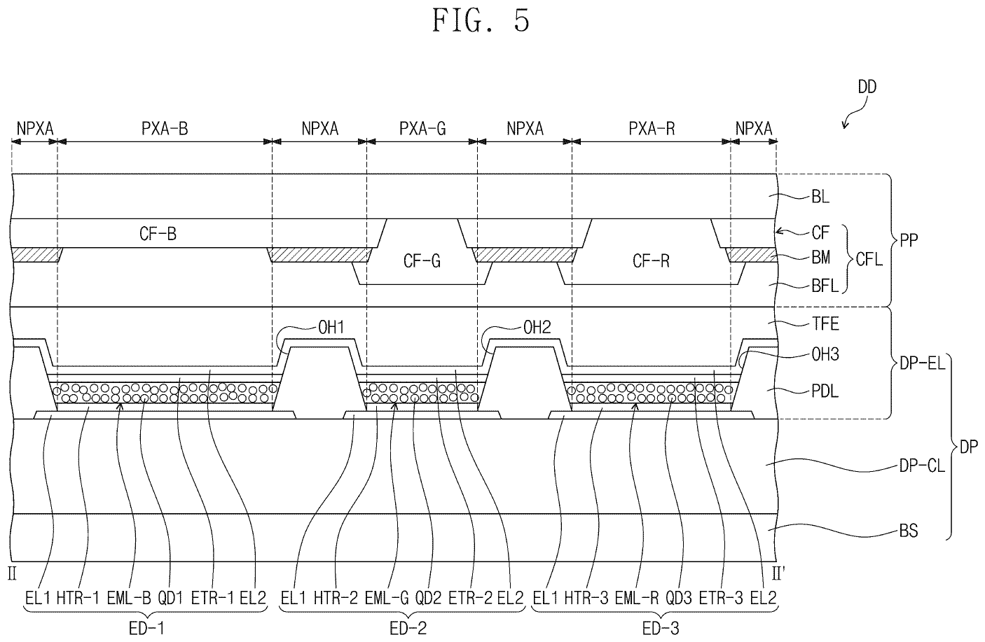

The display device DD may include a plurality of light-emitting elements ED-1, ED-2, and ED-3 (see FIG. 5). The optical member PP may be disposed on the display panel DP to control reflected light due to external light on the display panel DP. The optical member PP may include, for example, a polarization layer or a color filter layer.

In the display device DD according to an embodiment, the display panel DP may be a luminescent display panel. For example, the display panel DP may be a quantum dot light-emitting display panel including a quantum dot light-emitting element. However, an embodiment of the present disclosure is not limited thereto, and the display panel DP may be an organic light-emitting display panel including an organic electroluminescence element.

The display panel DP may include a base substrate BS, a circuit layer disposed on the base substrate BS, and a display element layer DP-EL disposed on the circuit layer DP-CL.

The base substrate BS may be a member providing a base surface on which the display element layer DP-EL is disposed. The base substrate BS may be a glass substrate, a metal substrate, a plastic substrate, etc. However, an embodiment of the present disclosure is not limited thereto, and the base substrate BS may be an inorganic layer, an organic layer, or a complex material layer. The base substrate BS may be a flexible substrate that may be easily bent or folded.

In an embodiment, the circuit layer DP-CL may be disposed on the base substrate BS, and include a plurality of transistors (not illustrated). For Example, the circuit layer DP-CL may include a switching transistor and a driving transistor for driving the light-emitting element of the display element layer DP-EL.

FIG. 4 is a plan view illustrating a display device DD according to an embodiment. FIG. 5 is a cross-sectional view of the display device DD according to an embodiment. FIG. 5 is a cross-sectional view taken along the line II-II′ in FIG. 4.

Referring to FIGS. 4 and 5, the display device DD according to an embodiment includes a plurality of light-emitting elements ED-1, ED-2, and ED-3. In some embodiments, the display device DD according to an embodiment may include a display panel DP, which includes a plurality of the light-emitting elements ED-1, ED-2, and ED-3, and an optical member PP disposed on the display panel DP. In some embodiments, in the display device DD according to an embodiment, the optical member PP may not be provided.

The display panel DP may include a base substrate BS, and a circuit layer DP-CL and a display element layer DP-EL which are disposed on the base substrate BS, and the display element layer DP-EL may include a pixel defining film PDL, light-emitting elements ED-1, ED-2, and ED-3 disposed between the pixel defining films PDLs, and an encapsulation layer TFE disposed on the light-emitting elements ED-1, ED-2, and ED-3.

The display device DD may include a peripheral region NPXA and light-emitting regions PXA-B, PXA-G, and PXA-R. The light-emitting regions PXA-B, PXA-G, and PXA-R may be each a region emitting light generated in the light-emitting elements ED-1, ED-2, and ED-3, respectively. The light-emitting regions PXA-B, PXA-G, and PXA-R may be spaced apart from each other on a plane.

The light-emitting regions PXA-B, PXA-G, and PXA-R may be divided into a plurality of groups according to color of light generated in the light-emitting elements ED-1, ED-2, and ED-3. In the display device DD according to an embodiment, illustrated in FIGS. 4 and 5, three light-emitting regions PXA-B, PXA-G, and PXA-R may be configured to emit blue light, green light, and red light, respectively are illustrated as examples. For example, the display device DD according to an embodiment may include the blue light-emitting region PXA-B, the green light-emitting region PXA-G, and the red light-emitting region PXA-R, which are distinguished from each other.

The plurality of the light-emitting elements ED-1, ED-2, and ED-3 may be configured to emit light in a different wavelength range from each other. For example, the display device DD according to an embodiment may include the first light-emitting element ED-1 configured to emit blue light, which is a first light, the second light-emitting element ED-2 configured to emit green light, which is a second light, and the third light-emitting element ED-3 configured to emit red light, which is a third light. However, an embodiment of the present disclosure is not limited thereto, and the first to third light-emitting elements ED-1, ED-2, and ED-3 may be configured to emit light in substantially the same wavelength range, or at least one light-emitting element may be configured to emit light in a different wavelength range.

For example, the blue light-emitting region PXA-B, the green light-emitting region PXA-G, and the third light-emitting region PXA-R, of the display device DD may correspond to the first light-emitting element ED-1, the second light-emitting element ED-2 and the third light-emitting element ED-3, respectively.

The display device DD according to an embodiment may include a plurality of the light-emitting elements ED-1, ED-2, and ED-3, and the light-emitting elements ED-1, ED-2, and ED-3 may include emission layers EML-B, EML-G, and EML-R containing quantum dots QD1, QD2, and QD3.

The first emission layer EML-B of the first light-emitting element ED-1 may include a first quantum dot QD1. The first quantum dot QD1 may be configured to emit blue light, which is the first light. The second emission layer EML-G of the second light-emitting element ED-2 and the third emission layer EML-R of the third light-emitting element ED-3 may include a second quantum dot QD2 and a third quantum dot QD3, respectively. The second quantum dot QD2 and the third quantum dot QD3 may be configured to emit green light, which is the second light, and red light, which is the third light, respectively.

In an embodiment, the first light may have a center wavelength in a wavelength range of about 410 nm to about 480 nm, the second light may have a center wavelength in a wavelength range of about 500 nm to about 570 nm, and the third light may have a center wavelength in a wavelength range of about 625 nm to about 675 nm.

As utilized herein, the quantum dot refers to a crystal of a semiconductor compound. The quantum dot may be configured to emit light having one or more suitable emission wavelengths depending on a size of the crystal. The quantum dot may be configured to emit light having one or more suitable emission wavelengths by adjusting a ratio of elements in the quantum dot compound.

The quantum dot may have a diameter of, for example, about 1 nm to about 10 nm.

The quantum dot may be synthesized by a wet chemical process, an organic metal chemical vapor deposition process, a molecular beam epitaxy process, or similar processes.

The wet chemical process is a method in which an organic solvent and a precursor material are mixed to then grow a crystal of quantum dot particles. When the crystal is grown, the organic solvent may naturally serve as a dispersant that is coordinated to a surface of a quantum dot crystal and may adjust the growth of the crystal. Therefore, the wet chemical process may control the growth of the quantum dot particles through a simpler and more cost-effective process than a vapor deposition method such as metal organic chemical vapor deposition (MOCVD) or molecular beam epitaxy (MBE).

The quantum dots QD1, QD2, and QD3 included in the emission layer EML according to an embodiment may be a semiconductor nanocrystal selected from among a Group II-VI compound, a Group Ill-V compound, a Group Ill-VI compound, a Group I-III-VI compound, a Group IV-VI compound, a Group IV element, a Group IV compound, and a combination thereof.

The Group II-VI compound may be selected from among the group consisting of: a binary compound selected from among the group consisting of CdSe, CdTe, CdS, ZnS, ZnSe, ZnTe, ZnO, HgS, HgSe, HgTe, MgSe, MgS and a mixture thereof; a ternary compound selected from among the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof; and a quaternary compound selected from among the group consisting of HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof. In some embodiments, the Group II-VI semiconductor compound may further include a Group I metal and/or a Group IV element. The Group I-II-VI compound may be selected from among CuSnS or CuZnS, and as the Group II-IV-VI compound, ZnSnS and/or the like may be selected. The Group I-II-IV-VI compound may be selected from among quaternary compounds selected from among the group consisting of Cu₂ZnSnS₂, Cu₂ZnSnS₄, Cu₂ZnSnSe₄, Ag₂ZnSnS₂ and a mixture thereof.

The Group III-VI compound may include a binary compound such as In₂S₃, In₂Se₃, a ternary compound such as InGaS₃, InGaSe₃, or any combination thereof.

The Group I-III-VI compound may be selected from among the group consisting of: ternary compounds selected from among the group consisting of AgInS, AgInS₂, CuInS, CuInS₂, AgGaS₂, CuGaS₂, CuGaO₂, AgGaO₂, AgAlO₂ and a mixture thereof; or quaternary compounds such as AgInGaS₂, CuInGaS2.

The Group III-V compound may be selected from among the group consisting of: binary compounds selected from among the group consisting of GaN, GaP, GaAs, GaSb, AlN, AlP, AlAs, AlSb, InN, InP, InAs, InSb and a mixture thereof; ternary compounds selected from among the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb and a mixture thereof; and quaternary compounds consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and a mixture thereof. In some embodiments, the Group Ill-V compound may further include a Group II metal. For example, InZnP and/or the like may be selected as a Group III-II-V compound.

The Group IV-VI compound may be selected from among the group consisting of: binary compounds selected from among the group consisting of SnS, SnSe, SnTe, PbS, PbSe, PbTe, and a mixture thereof; ternary compounds selected from among the group consisting of SnSeS, SnSeTe, SnSTe, PbSeS, PbSeTe, PbSTe, SnPbS, SnPbSe, SnPbTe and a mixture thereof; and quaternary compounds selected from among the group consisting of SnPbSSe, SnPbSeTe, SnPbSTe.

An example of the Group II-IV-V semiconductor compound may be a ternary compound selected from among the group consisting of ZnSnP, ZnSnP₂, ZnSnAs₂, ZnGeP₂, ZnGeAs₂, CdSnP₂, CdGeP₂ and a mixture thereof.

The Group IV element may be selected from among the group consisting of Si, Ge, and a mixture thereof. The Group IV compound may be a binary compound selected from among the group consisting of SiC, SiGe, and a mixture thereof.

Each element included in the multi-component compounds such as the binary compound, the ternary compound, and the quaternary compound may be present in particles at a substantially uniform concentration or a substantially non-uniform concentration. For example, Formula above may refer to types (kinds) of the elements included in the compound, and an element ratio in the compound may differ. For example, AgInGaS₂ may refer to AgInₓGa₁₋ₓS₂ (where x is a real number between 0 to 1).

In this case, the binary compound, the ternary compound, or the quaternary compound may be present in particles at a substantially uniform concentration or may be present in substantially the same particles in which a concentration distribution may be divided into partially different states. In some embodiments, the binary compound, the ternary compound, or the quaternary compound may also have a core/shell structure in which one quantum dot surrounds another quantum dot. The core/shell structure may have a concentration gradient that the concentration of the elements present in the shell may decrease gradually toward the core.

In some embodiments, the quantum dots QD1, QD2, and QD3 may have a core-shell structure including a core containing the above-described nanocrystal, and a shell around (e.g., surrounding) the core. The shell of the quantum dots QD1, QD2, and QD3 may serve as a protective layer for preventing or reducing the core from chemical alteration to maintain semiconductor characteristics and/or a charging layer for imparting electrophoretic properties to the quantum dot. The shell may be a single layer or a multilayer. Examples of the shell of the quantum dots QD1, QD2, and QD3 may include a metal or non-metal oxide, a semiconductor compound, or a combination thereof.

For example, examples of the metal or non-metal oxide may include: binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO; or ternary compounds such as MgAl₂O₄, CoFe₂O₄, NiFe₂O₄, CoMn₂O₄, but the present disclosure is not limited thereto.

In some embodiments, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc. However, the present disclosure is not limited thereto.

The quantum dots QD1, QD2, and QD3 may have a full width of half maximum (FWHM) of an emission wavelength spectrum of about 45 nm or less, about 40 nm or less, and about 30 nm or less. When FWHM falls within this range, color purity or color reproducibility may be improved. In some embodiments, light emitted through the quantum dots QD1, QD2, and QD3 may be emitted in all directions, and thus an optical viewing angle may be improved.

In some embodiments, the form of the quantum dots QD1, QD2, and QD3 is not particularly limited as long as it is a form commonly utilized in the art, but, more specifically the quantum dots include (e.g., in the form of) spherical, pyramidal, multi-arm, or cubic nanoparticles, nanotubes, nanowires, nanofibers, nanoplatelets, and/or the like may be utilized.

The quantum dots QD1, QD2, and QD3 may adjust an energy band gap by adjusting a size of the quantum dot or adjusting an element ratio in the quantum dot compound, and thus light with one or more suitable wavelengths may be emitted in the quantum dot emission layer. Therefore, when the quantum dots as previously described (quantum dots having different sizes or having different element ratios in the quantum dot compound) are utilized, a light-emitting element configured to emit light with one or more suitable wavelengths may be achieved. For example, adjustments in sizes of the quantum dots QD1, QD2, and QD3 and the element ratios in the quantum dot compound may be selected for red, green, and/or blue light to be emitted. In some embodiments, the quantum dots QD1, QD2, and QD3 may be configured to emit white light by combining one or more suitable colors of light.

In the quantum dots QD1, QD2, and QD3, the colors of light emitted may be adjusted depending on the size of the particle, and thus the quantum dots QD1, QD2, and QD3 may have a variety of emission colors such as blue, red color, or green. The smaller the particle size of the quantum dots QD1, QD2, and QD3, the more likely light is to be emitted in the short wavelength region. For example, the quantum dot emitting green light may have a smaller particle size than the quantum dot emitting red light, among the quantum dots QD1, QD2, and QD3, which have the same core. In some embodiments, the quantum dot emitting blue light may have a smaller particle size than the quantum dot emitting green light, among the quantum dots QD1, QD2, and QD3, which have the same core. However, an embodiment of the present disclosure is not limited thereto, and, even in the quantum dots QD1, QD2, and QD3, which have the same core, the particle size may be adjusted depending on forming materials of the shell, a thickness of the shell, and/or the like.

In some embodiments, when the quantum dots QD1, QD2, and QD3 have a variety of emission colors such as blue, red, and green, in the quantum dots QD1, QD2, and QD3, which each have a different emission color, materials of the core of may be different from each other.

In an embodiment, each of the first to third quantum dots QD1, QD2, and QD3 may have a different diameter from each other. For example, the first quantum dot QD1 utilized in the first light-emitting element ED-1 configured to emit light in a relatively short wavelength range may have a relatively smaller average diameter than the second quantum dot QD2 of the second light-emitting element ED-2 and the third quantum dot QD3 of the third light-emitting element ED-3, which is configured to emit light in relatively long wavelength ranges.

In some embodiments, as utilized herein, the average diameter corresponds to an arithmetic mean of the diameters of a plurality of the quantum dot particles. In some embodiments, the diameter of the quantum dot may be an average value of widths of the quantum dot particle on a cross-section.

A relation with the average diameter of the first to third quantum dots QD1, QD2, and QD3 is not limited to the above-described limitations. For example, although FIG. 5 shows that the first to third quantum dots QD1, QD2, and QD3 have similar sizes to each other, unlike what is illustrated, the first to third quantum dots QD1, QD2, and QD3 included in the light-emitting elements ED-1, ED-2, and ED-3 may have different sizes from each other. In some embodiments, the average diameter of two quantum dots selected from among the first to third quantum dots QD1, QD2, and QD3 may be similar, and the rest may be different.

In the light-emitting elements ED-1, ED-2, and ED-3 according to an embodiment, the emission layers EML-B, EML-G, and EML-R may include a host and a dopant. In an embodiment, the emission layers EML-B, EML-G, and EML-R may include the quantum dots QD1, QD2, and QD3 as a dopant material. In some embodiments, in an embodiment, the emission layers EML-B, EML-G, and EML-R may further include a host material. In some embodiments, in the light-emitting elements ED-1, ED-2 and ED-3, the emission layers EML-B, EML-G, and EML-R may be configured to emit fluorescence. For example, the quantum dots QD1, QD2, and QD3 may be utilized as a fluorescent dopant material.

In some embodiments, in each of the first to third quantum dots QD1, QD2, and QD3, a ligand and/or the like may also be chemically bonded to a surface thereof in order to improve dispersibility.

In the display device DD illustrated in FIGS. 4 and 5, the emission regions PXA-B, PXA-G, and PXA-R may each have a different area. In this case, the area may indicate an area when viewed on a plane (e.g., in a plan view) defined by the first direction DR1, and the second direction DR2.

The emission regions PXA-B, PXA-G, and PXA-R may have different areas depending on colors of light emitted in the emission layers EML-B, EML-G, and EML-R of the light-emitting elements ED-1, ED-2, and ED-3. For example, referring to FIGS. 4 and 5, in the display device DD according to an embodiment, the blue emission region PXA-B corresponding to the first light-emitting element ED-1 configured to emit blue light may have a greatest area, and the green emission region PXA-G corresponding to the second light-emitting element ED-2 configured to emit green light may have a smallest area. However, an embodiment of the present disclosure is not limited thereto, and the emission regions PXA-B, PXA-G, and PXA-R may be configured to emit light of a color other than blue, green, and red. In some embodiments, the emission regions PXA-B, PXA-G, and PXA-R may have the same area, or the emission regions PXA-B, PXA-G, and PXA-R may be provided at a different area ratio from what is illustrated in FIG. 4.

The emission regions PXA-B, PXA-G, and PXA-R may be each a region separated by the pixel-defining film PDL. Peripheral regions NPXAs may be regions between the neighboring emission regions PXA-B, PXA-G, and PXA-R, and may correspond to the pixel-defining film PDL. In some embodiments, as utilized herein, the emission regions PXA-B, PXA-G, and PXA-R may correspond to pixels, respectively. The pixel-defining film PDL may separate the light-emitting elements ED-1, ED-2, and ED-3. The emission layers EML-B, EML-G, and EML-R of the light-emitting elements ED-1, ED-2, and ED-3 may be disposed in openings OH defined in the pixel-defining films PDL to be separated. In an embodiment, the first emission layer EML-B of the first light-emitting element ED-1 may be disposed in a first opening OH1, the second emission layer EML-G of the second light-emitting element ED-2 may be disposed in a second opening OH2, and the third emission layer EML-R of the third light-emitting element ED-3 may be disposed in a third opening OH3.

The pixel-defining film PDL may be formed of a polymer resin. For example, the pixel-defining film PDL may be formed including a polyacrylate-based resin or a polyimide-based resin. In some embodiments, the pixel-defining film PDL may be formed by further including an inorganic material in addition to the polymer resin. In some embodiments, the pixel-defining film PDL may be formed including a light-absorbing material or may be formed including a black pigment or a black dye. The pixel-defining film PDL formed including the black pigment or the black dye may achieve a black pixel-defining film. In the forming of the pixel-defining film PDL, carbon black and/or the like may be utilized as the black pigment or the black dye, but an embodiment of the present disclosure is not limited thereto.

In some embodiments, the pixel-defining film PDL may be formed of an inorganic material. For example, the pixel-defining film PDL may be formed including silicon nitride (SiNₓ), silicon oxide (SiOₓ), silicon oxynitride (SiOₓN_{y}), silicon oxide-nitride (SiNₓO_{y}), and/or the like. The pixel-defining film PDL may define the emission regions PXA-B, PXA-G, and PXA-R. The emission regions PXA-B, PXA-G, and PXA-R and the peripheral region NPXA may be separated by the pixel-defining film PDL.

The light-emitting elements ED-1, ED-2, and ED-3 may each include a first electrode EL1, one selected from among hole transport regions HTR-1, HTR-2, and HTR-3 disposed on the first electrode EL1, one selected from among emission layers EML-B, EML-G, and EML-R disposed on the one selected from among the hole transport regions HTR-1, HTR-2, and HTR-3, one selected from among electron transport regions ETR-1, ETR-2, and ETR-3 disposed on the one selected from among the emission layers EML-B, EML-G, and EML-R, and a second electrode E12 disposed on the one selected from among electron transport regions ETR-1, ETR-2, and ETR-3.

The hole transport regions HTR-1, HTR-2, and HTR-3 and the electron transport regions ETR-1, ETR-2, and ETR-3 included in the light-emitting elements ED-1, ED-2, and ED-3 may be disposed in the openings OH1, OH2, and OH3 defined in the pixel defining film PDL to be separated.

For example, the first hole transport region HTR-1 and the first electron transport region ETR-1, each included in the first light-emitting element ED-1, may be disposed adjacent to the first emission layer EML-B, and may be patterned to be disposed within the first opening OH1 in which the first emission layer EML-B is disposed. The second hole transport region HTR-2 and the second electron transport region ETR-2, each included in the second light-emitting element ED-2, may be disposed adjacent to the second emission layer EML-G and may be patterned to be disposed within the second opening OH2 in which the second emission layer EML-G is disposed. The third hole transport region HTR-3 and the third electron transport region ETR-3, each included in the third light-emitting element ED-3, may be disposed adjacent to the third emission layer EML-R, and may be patterned to be disposed within the third opening OH3 in which the third emission layer EML-R is disposed.

However, an embodiment of the present disclosure is not limited thereto, and the hole transport regions HTR-1, HTR-2, and HTR-3 and the electron transport regions ETR-1, ETR-2, and ETR-3 may be provided as a common layer which are commonly disposed on the pixel regions PXA-B, PXA-G, and PXA-R and the peripheral regions NPXA.

In an embodiment, each of the hole transport regions HTR-1, HTR-2, and HTR-3 and the electron transport regions ETR-1, ETR-2, and ETR-3 may be provided within the openings OH1, OH2, and OH3 defined in pixel-defining film PDL through a printing process.

An encapsulation layer TFE may cover the light-emitting elements ED-1, ED-2, and ED-3. The encapsulation layer TFE may seal the display element layer DP-EL. The encapsulation layer TFE may be a thin film encapsulation layer. The encapsulation layer TFE may be a layer in which a single layer or a plurality of layers are stacked. The encapsulation layer TFE may include at least one insulating layer. The encapsulation layer TFE according to an embodiment may include at least one inorganic layer (hereinafter, referred to as an encapsulation inorganic layer). In some embodiments, the encapsulation layer TFE according to an embodiment may include at least one organic layer (hereinafter, referred to as an encapsulation organic layer) and at least one encapsulation inorganic layer.

The encapsulation inorganic layer may protect the display element layer DP-EL from moisture/oxygen, and the encapsulation organic layer may protect the display element layer DP-EL from foreign materials such as dust particles. The encapsulation inorganic layer may include silicon nitride, silicon oxynitride, silicon oxide, titanium oxide, aluminum oxide, and/or the like, but is not particularly limited thereto. The encapsulation organic layer may include an acryl-based compound, an epoxy-based compound, and/or the like. The encapsulation organic layer may include a photopolymerizable organic material but is not particularly limited.

The encapsulation layer TFE may be disposed on the second electrode EL2 and may be disposed to fill a portion of the openings OH1, OH2, and OH3.

In some embodiments, the emission layers EML-B, EML-G, and EML-R of the first to third light-emitting elements ED-1, ED-2, and ED-3 each have a similar thickness in the display device DD according to an embodiment illustrated in FIG. 5, but an embodiment of the present disclosure is not limited thereto. For example, in an embodiment, the emission layers EML-B, EML-G, and EML-R of the first to third light-emitting elements ED-1, ED-2, and ED-3 may each have a different thickness. In some embodiments, the hole transport regions HTR-1, HTR-2, and HTR-3 and the electron transport regions ETR-1, ETR-2, and ETR-3 of the first to third light-emitting elements ED-1, ED-2, and ED-3 may also each have a different thickness.

Referring to FIG. 4, blue emission regions PXA-Bs, and red emission regions PXA-Rs may be arranged by turns along the first direction DR1 to configure a first group PXG1. Green emission regions PXA-Gs may be arranged along the first direction DR1 to configure a second group PXG2.

The first group PXG1 may be disposed spaced (e.g., spaced and/or apart) from the second group PXG2 in a second direction DR2. The first group PXG1 and the second group PXG2 may be each provided in plurality. The first groups PXG1s and the second groups PXG2s may be arranged by turns along the second direction DR2.

One of the green emission regions PXA-Gs may be disposed spaced (e.g., spaced and/or apart) from one selected from among the blue emission regions PXA-Bs or one selected from among red emission regions PXA-Rs in a fourth direction DR4. The fourth direction DR4 may be a direction between the first direction DR1 and the second direction DR2.

An arrangement structure of the emission regions PXA-B, PXA-G, and PXA-R illustrated in FIG. 4 may be named as a pentile structure. However, in the display device DD according to an embodiment, the arrangement structure of the emission regions PXA-B, PXA-G, and PXA-R is not limited to the arrangement structure illustrated in FIG. 4. For example, in an embodiment, the emission regions PXA-B, PXA-G, and PXA-R may have, along the first direction DR1, a stripe structure in which the blue emission region PXA-B, the green emission region PXA-G, and the red emission region PXA-R are sequentially disposed by turns.

Referring to FIGS. 3 and 5, the display device DD according to an embodiment may further include an optical member PP. The optical member PP may block or reduce external light provided from the outside of the display device DD to the display panel DP. The optical member PP may block or reduce some of the external light. The optical member PP may have an anti-reflection function, which minimizes reflected light due to the external light.

In an embodiment illustrated in FIG. 5, the optical member PP may include a base layer BL and a color filter layer CFL. The display device DD according to an embodiment may further include the color filter layer CFL disposed on the light-emitting elements ED-1, ED-2, and ED-3 of the display panel DP.

The base layer BL may be a member providing a base substrate on which the color filter layer CFL and/or the like are disposed. The base layer BL may be an organic substrate, a metal substrate, a plastic substrate, and/or the like. However, an embodiment of the present disclosure is not limited thereto, and the base layer BL may be an inorganic layer, an organic layer, or a complex material layer.

The color filter layer CFL may include a light-blocking part BM and a color filter part CF. The color filter part CF may include a plurality of filters CF-B, CF-G, and CF-R. For example, the color filter layer CFL may include the first filter CF-B configured to transmit a first light, the second filter CF-G configured to transmit a second light, and the third filter CF-R configured to transmit a third light. For example, the first filter CF-B may be a blue filter, the second filter CF-G may be a green filter, and the third filter CF-R may be a red filter.

The filters CF-B, CF-G, and CF-R may each include a polymer photosensitive resin and a pigment or a dye. The first filter CF-B may include a blue pigment or dye, the second filter CF-G may include a green pigment or dye, and the third filter CF-R may include a red pigment or dye.

In some embodiments, an embodiment of the present disclosure is not limited thereto, and the first filter CF-B may include no (e.g., exclude) pigment or dye. The first filter CF-B may include a polymer photosensitive resin and may include no pigment or dye. The first filter CF-B may be transparent. The first filter CF-B may be formed of a transparent photosensitive resin.

The light-blocking part BM may be a black matrix. The light-blocking part BM may be formed including an organic light-blocking material or an inorganic light-blocking material, which contains a black pigment or a black dye. The light-blocking part BM may prevent or reduce light leakage and separate boundaries between the adjacent filters CF-B, CF-G, and CF-R.

The color filter layer CFL may further include a buffer layer BFL. For example, the buffer layer BFL may be a protective layer protecting the filters CF-B, CF-G, and CF-R. The buffer layer BFL may be an inorganic layer including at least one inorganic material selected from among silicon nitride, silicon oxide, and silicon oxynitride. The buffer layer BFL may be formed of a single layer or a plurality of layers.

In an embodiment, FIG. 5 illustrates that the first filter CF-B of the color filter layer CFL overlaps the second filter CF-G and the third filter CF-R, but an embodiment of the present disclosure is not limited thereto. For example, the first to third filters CF-B, CF-G, and CF-R may be separated by the light-blocking part BM and may not overlap one another. In some embodiments, in an embodiment, each of the first to third filters CF-B, CF-G, and CF-R may be disposed corresponding to the blue emission region PXA-B, the green emission region PXA-G, and the red emission region PXA-R, respectively. In some embodiments, the color filter layer CFL may not be provided in the display device DD according to an embodiment.

Unlike what is illustrated in FIG. 5, the display device DD according to an embodiment may include a polarizing layer as the optical member PP in place of the color filter layer CFL. The polarizing layer may block or reduce external light provided from the outside to the display panel DP. The polarizing layer may block or reduce some of the external light.

In some embodiments, the polarizing layer may reduce reflected light that is generated on the display panel DP due to the external light. For example, the polarizing layer may function to block or reduce the reflected light of a case where light provided from the outside of the display device DD is incident to the display panel DP and exits again. The polarizing layer may be a circular polarizer having an anti-reflective function, or the polarizing layer may include a linear polarizer and a λ/4 phase retarder. In some embodiments, the polarizing layer may be disposed on the base layer BL to be exposed or the polarizing layer may be disposed below the base layer BL.

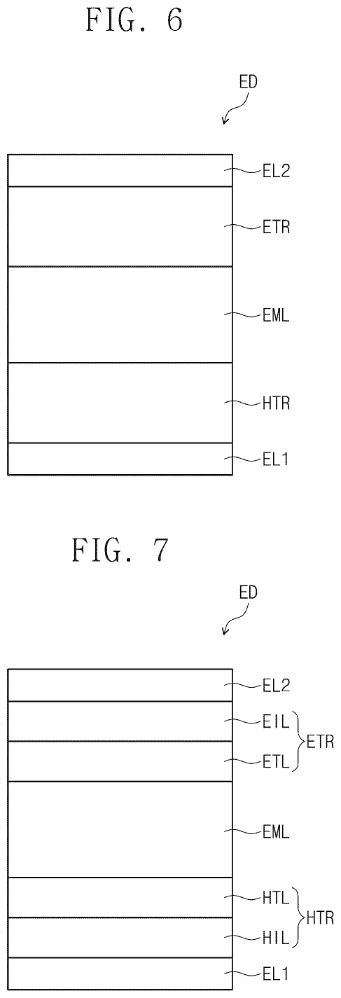

FIGS. 6 to 9 are cross-sectional views of the light-emitting element according to an embodiment of the present disclosure.

Referring to FIG. 6, the light-emitting element ED according to an embodiment may include a first electrode EL1, a hole transport region HTR, an emission layer EML, an electron transport region ETR, and a second electrode EL2, which are sequentially stacked.

FIG. 7 illustrates, compared to FIG. 6, a cross-sectional view of the light-emitting element ED according to an embodiment, in which the hole transport region HTR includes a hole injection layer HIL and a hole transport layer HTL and the electron transport region ETR includes an electron injection layer EIL and an electron transport layer ETL. In some embodiments, FIG. 8 illustrates, compared to FIG. 6, a cross-sectional view of the light-emitting element ED according to an embodiment in which the hole transport region HTR includes a hole injection layer HIL, a hole transport layer HTL, and an electron-blocking layer EBL, and the electron transport region ETR includes an electron injection layer EIL, an electron transport layer ETL, and a hole-blocking layer HBL. FIG. 9 illustrates, compared to FIG. 6, a cross-sectional view of the light-emitting element ED according to an embodiment, including a capping layer CPL disposed on the second electrode EL2.

In the light-emitting element ED according to an embodiment, the first electrode EL1 has conductivity (e.g., is a conductor). The first electrode EL1 may be formed of a metal alloy or a conductive compound. The first electrode EL1 may be an anode. The first electrode EL1 may be a pixel electrode.

In the light-emitting element ED according to an embodiment, the first electrode EL1 may be a reflective electrode. However, an embodiment of the present disclosure is not limited thereto. For example, the first electrode EL1 may be a transmissive electrode, or a transflective electrode. When the first electrode EL1 is a transflective electrode, or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, or a compound thereof or a mixture thereof (For example, a mixture of Ag and Mg). In some embodiments, the first electrode EL1 may be a multi-layered structure including a reflection film or a transflective film, each formed of the above-described materials, and a transparent conductive film formed of indium tin oxide (ITO), indium zinc oxide (IZO), zinc oxide (ZnO), indium tin zinc oxide (ITZO), and/or the like. For example, the first electrode EL1 may be a multi-layered metal film and may have a structure in which a metal film of ITO/Ag/ITO is stacked.

The hole transport region HTR is provided on the first electrode EL1. The hole transport region HTR may include a hole injection layer HIL, a hole transport layer HTL, etc. In some embodiments, the hole transport region HTR may further include at least one selected from among a hole buffer layer and an electron-blocking layer (EBL) in addition to the hole injection layer HIL and the hole transport layer HTL. The hole buffer layer may compensate for a resonance distance according to a wavelength of light emitted from the emission layer EML, and thus luminous efficiency may be improved. The materials that may be included in the hole transport region HTR may be utilized as a material included in a hole buffer layer. The electron-blocking layer EBL serves to prevent or reduce electrons from being injected from the electron transport region ETR to the hole transport region HTR.

The hole transport region HTR may have a single layer formed of a single material, a single layer formed of a plurality of different materials, or a multi-layered structure having a plurality of layers formed of a plurality of different materials. For example, the hole transport region HTR may have a single layer structure formed of a plurality of different materials, or may have a structure of a hole injection layer HIL/hole transport layer HTL, a hole injection layer HIL/hole transport layer HTL/hole buffer layer, a hole injection layer HIL/hole buffer layer, a hole transport layer HTL/hole buffer layer, a hole injection layer HIL/hole transport layer HTL/electron-blocking layer EBL, and/or the like, which are sequentially stacked from the first electrode EL1. However, an embodiment of the present disclosure is not limited thereto.

The hole transport region HTR may be formed utilizing one or more suitable methods such as a vacuum deposition method, a spin coating method, a casting method, the Langmuir-Blodgett (LB) method, an inkjet printing method, a laser printing method, and a laser-induced thermal imaging (LITI) method.

The hole injection layer HIL may include, for example, a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris{N,-(2-naphthyl)-N-phenylamino}-triphenylamine (2-TNATA), poly(3,4-ethylenedioxythiophene)/poly(4-styrenesulfonate) (PEDOT/PSS), (polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPD), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HAT-CN), etc.

The hole transport layer HTL may include a general material suitable in the technical art. For example, the hole transport layer HTL may further include a carbazole-based derivative such as N-phenylcarbazole and polyvinylcarbazole, a fluorine-based derivative, a triphenylamine-based derivative such as N,N′-bis(3-methylphenyl)-N,N′-diphenyl-[1,1-biphenyl]-4,4′-diamine (TPD), 4,4′,4″-tris(N-carbazolyl)triphenylamine (TCTA), N,N′-di(naphthalene-1-yl)-N,N′-diphenyl-benzidine (NPD), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may have a thickness of about 5 nm to about 1500 nm, and for example, about 10 nm to about 500 nm. The hole injection layer HIL may have a thickness of, for example, about 3 nm to about 100 nm, and the hole transport layer HTL may have a thickness of about 3 nm to about 100 nm. For example, the electron-blocking layer EBL may have a thickness of about 1 nm to about 100 nm. When the thicknesses of the hole transport region HTR, the hole injection layer HIL, the hole transport layer HTL, and the electron-blocking layer EBL fall within the above-described ranges, hole transport characteristics to a satisfactory degree may be obtained without a substantial increase in a driving voltage.

The emission layer EML is provided on the hole transport region HTR. The emission layer EML may have a thickness of, for example, about 10 nm to about 100 nm, or about 10 nm to about 30 nm. The emission layer EML may have a single layer formed of a single material, a single layer formed of a plurality of different materials, or a multi-layered structure having a plurality of layers formed of a plurality of different materials. In the light-emitting element ED according to an embodiment, the emission layer EML may include quantum dots QD1, QD2, and QD3 (see FIG. 5).

The emission layer EML may be formed utilizing one or more suitable methods such as a vacuum deposition method, a spin coating method, a casting method, the Langmuir-Blodgett (LB) method, an inkjet printing method, a laser printing method, and/or a laser-induced thermal imaging (LITI) method. In an embodiment, the emission layer EML may be formed by providing a quantum dot composition including the quantum dots QD1, QD2, and QD3 (see FIG. 5) through an inkjet printing method.

In the light-emitting element ED according to an embodiment, the electron transport region ETR may be provided on the emission layer EML. The electron transport region ETR may include at least one selected from among the hole-blocking layer HBL, the electron transport layer ETL, and the electron injection layer EIL, but an embodiment of the present disclosure is not limited thereto.

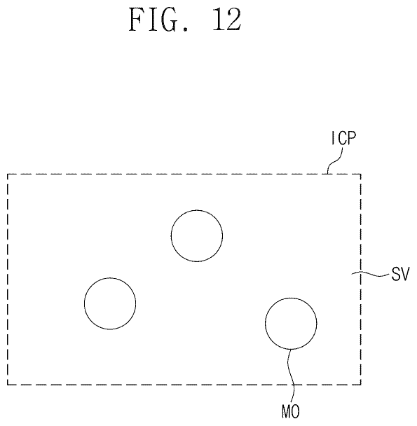

The electron transport region ETR may include an inorganic particle MO (see FIG. 12). The inorganic particle MO (see FIG. 12) included in the electron transport region ETR may be a metal oxide containing zinc (Zn) and a first metal. The inorganic particle MO (see FIG. 12) may be the metal oxide in which the first metal is doped to zinc. In an embodiment, the first metal may have a larger bond dissociation energy with oxygen than zinc. In an embodiment, the first metal may be tin (Sn), copper (Cu), or nickel (Ni). The inorganic particle MO will be described later in more detail.

The electron transport region ETR may be formed of an electron transport composition ICP (see FIG. 12), which will be described later. For example, the electron transport region ETR may be formed of the electron transport composition ICP (see FIG. 12) containing an inorganic particle MO (see FIG. 12) and a solvent SV (see FIG. 12).

Characteristics of the quantum dots QD1, QD2, and QD3 (see FIG. 5)-based element may be determined by quantum efficiency of the quantum dots QD1, QD2, and QD3 (see FIG. 5), a charge carrier balance, light extraction efficiency, a leakage current, etc. For example, for improving the luminous efficiency of the light-emitting element ED including quantum dots QD1, QD2, and QD3 in the emission layer EML, methods such as adjusting excitons to be confinement to the emission layer, adjusting holes and electrons to be smoothly transported to the quantum dots QD1, QD2, and QD3, preventing or reducing a leakage current and/or the like, may be utilized. For this, a method utilizing a metal oxide material such as ZnO, or ZnMgO may be utilized in the electron transport region ETR of the quantum dots QD1, QD2, and QD3 (see FIG. 5)-based light-emitting element ED. However, in a case of the electron transport region utilizing the metal oxide such as ZnO or ZnMgO, an injection rate of the electrons may be faster than an injection rate of the holes, and thus there is a limitation in that the charge carrier balance in the emission layer EML may be disrupted and thus the luminous efficiency and the element lifespan may decrease.

As utilized herein, because the inorganic particle MO (see FIG. 12) containing zinc and the first metal having the higher bond dissociation energy with oxygen than zinc (Zn) are utilized in the electron transport region ETR, the electron injection rate in the electron transport region ETR may be adjusted, and thus the charge injection balance of the light-emitting element ED may be improved, and surface stability of the metal oxide may be stabilized, resulting in improvements in processability. Therefore, the light-emitting element including the electron transport region ETR including the inorganic particle MO (see FIG. 12) may have excellent or suitable luminous efficiency and improved element lifespan.

The electron transport region ETR may have a single layer formed of a single material, a single layer formed of a plurality of different materials, or a multi-layered structure having a plurality of layers formed of a plurality of different materials.

For example, the electron transport region ETR may have a single-layer structure of the electron injection layer EIL or the electron transport layer ETL, or have a single-layer structure formed of the electron injection material and the electron transport material. In some embodiments, the electron transport region ETR may have a single layer structure formed of a plurality of different materials or may have a structure of an electron transport layer ETL/electron injection layer EIL, or a hole-blocking layer HBL/electron transport layer ETL/electron injection layer EIL, which are sequentially stacked from the emission layer EML. However, an embodiment of the present disclosure is not limited thereto. The electron transport region ETR may have a thickness of, for example, about 20 nm to about 150 nm.

When the electron transport region ETR has a multi-layered structure having a plurality of layers, at least any layer among the plurality of layers may be formed of the electron transport composition according to an embodiment of the present disclosure. For example, the electron transport region ETR may include the electron transport layer ETL disposed on the emission layer EML, the electron injection layer EIL disposed on the electron transport layer ETL, and the electron transport layer ETL may be formed of the electron transport composition according to an embodiment.

The electron transport region ETR may be formed by one or more suitable methods such as a vacuum deposition method, a spin coating method, a casting method, the Langmuir-Blodgett (LB) method, an inkjet printing method, a laser printing method, a laser-induced thermal imaging (LITI) method, etc. In an embodiment, the electron transport region ETR may be formed by providing an electron transport composition including the inorganic particle MO (see FIG. 12) and a solvent SV (see FIG. 12) through the inkjet printing method.

In an embodiment, the electron transport region ETR may further include an inorganic material suitable in the art or an organic material suitable in the art.

When the electron transport region ETR includes the electron transport layer ETL, the electron transport region ETR may include an anthracene-based compound. However, an embodiment of the present disclosure is not limited thereto, and the electron transport region may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, bis[2-(diphenylphosphino)phenyl]ether oxide (DPEPO), 2-(4-(N-phenylbenzimidazolyl-1-ylphenyl)-9,10-dinaphthylanthracene, 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (Balq), berylliumbis(benzoquinolin-10-olate (Bebq₂), 9,10-di(naphthalen-2-yl)anthracene (ADN), or a mixture thereof. The electron transport layer ETL may have a thickness of about 10 nm to about 100 nm, and for example, about 15 nm to about 50 nm. When the thickness of the electron transport layer ETL falls within the above-described range, electron transport characteristics to a satisfactory degree may be obtained without a substantial increase in the driving voltage.

When the electron transport region ETR includes the electron injection layer EIL, a halogenated metal such as LiF, NaCl, CsF, RbCl, and RbI, a lanthanide metal such as Yb, a metal oxide such as Li₂O, BaO, or lithium quinolate (LiQ) may be utilized in the electron transport region ETR but is not limited thereto. The electron injection layer EIL may be also formed of a material in which an electron transport material and a conductive organo metal salt are mixed. For example, the organo metal salt may include a metal acetate, a metal benzoate, a metal acetoacetate, a metal acetylacetonate, or a metal stearate. The electron injection layers EILs may have a thickness of about 0.1 nm to about 10 nm, or about 0.3 nm to about 9 nm. When the thicknesses of the electron injection layer EILs fall within the above-described ranges, electron injection characteristics to a satisfactory degree may be obtained without a substantial increase in the driving voltage.

The electron transport region ETR may include, as previously described, a hole-blocking layer HBL. The hole-blocking layer HBL, for example, at least one selected from among 2,9-dimethyl-4,7-diphenyl-1,10-phenanthroline (BCP) and 4,7-diphenyl-1,10-phenanthroline (Bphen), but is not limited thereto.

The second electrode EL2 may be provided on the electron transport region ETR. The second electrode EL2 may be a common electrode or a negative electrode. The second electrode EL2 may be a transmissive electrode, a transflective electrode, or a reflective electrode. When the second electrode EL2 is a transmissive electrode, the second electrode EL2 may be formed of a transparent metal oxide such as indium tin oxide (ITO), indium zinc oxide (IZO), zinc oxide (ZnO), and indium tin zinc oxide (ITZO).

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, or a compound or a mixture (for example, a mixture of Ag and Mg), each including the same. In some embodiments, the second electrode EL2 may have a multilayered structure including a reflective film or a transflective film, each formed of the above-described materials, or a transparent conductive film formed of indium tin oxide (ITO), indium zinc oxide (IZO), zinc oxide (ZnO), indium tin zinc oxide (ITZO), etc.

In some embodiments, the second electrode EL2 may be connected to an auxiliary electrode. When the second electrode EL2 is connected to the auxiliary electrode, a resistance of the second electrode EL2 may be reduced.

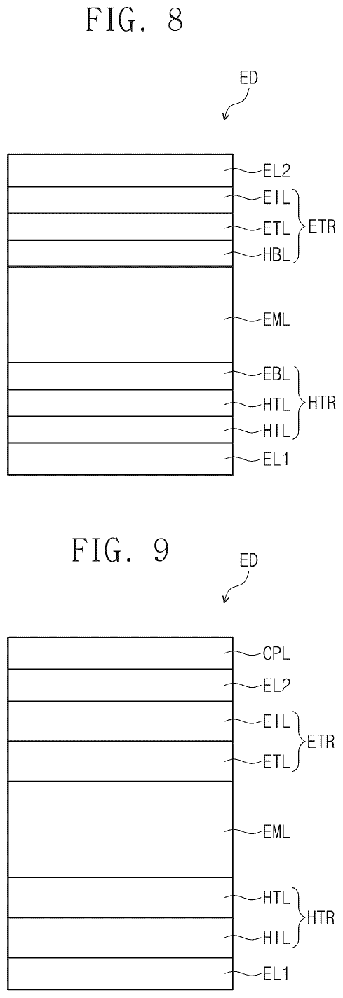

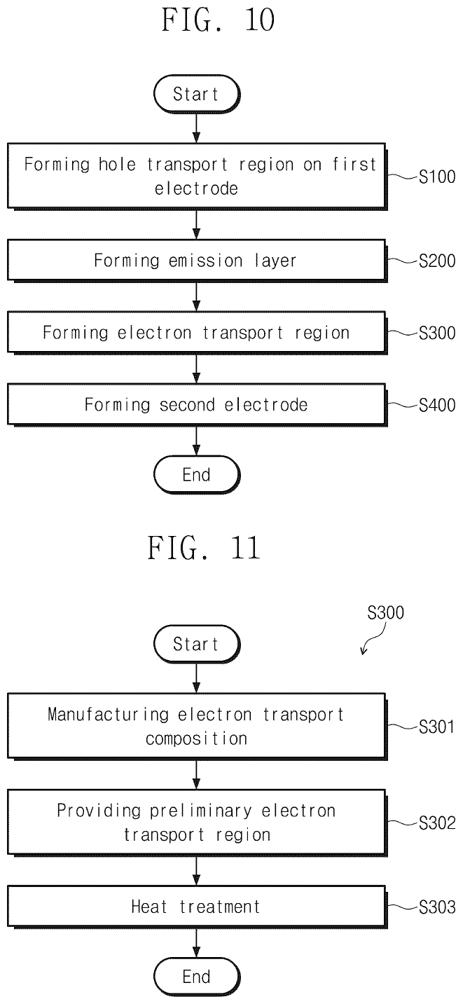

FIG. 10 is a flow chart showing a method for manufacturing a light-emitting element according to an embodiment. FIG. 11 is a detailed flow chart of the forming of an electron transport region according to an embodiment (S300).

Referring to FIG. 10, the method for manufacturing the light-emitting element according to an embodiment may include: forming a hole transport region on a first electrode (S100); forming an emission layer on the hole transport region (S200); forming an electron transport region on the emission layer (S300); and forming a second electrode on the electron transport region (S400).

Referring to FIG. 11, the forming of the electron transport region according to an embodiment (S300) may include: manufacturing an electron transport composition (S301); providing a preliminary electron transport region (S302); and performing a heat treatment of the preliminary electron transport region (S303).

FIG. 12 is a view schematically illustrating the electron transport composition ICP according to an embodiment. The electron transport composition ICP, according to an embodiment of the present disclosure may be a material forming the electron transport region of the light-emitting element. However, an embodiment of the present disclosure is not limited thereto, and the electron transport composition ICP according to an embodiment may be a material forming any one selected from among the hole transport region of the light-emitting element or functional layers included in the light-emitting element.

As utilized herein, a term “substituted or unsubstituted” may refer to being substituted or unsubstituted with at least one substituent selected from among the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a hetero ring group. In some embodiments, each of the substituents previously exemplified may be substituted or unsubstituted. For example, a biphenyl group may be construed as an aryl group, or a phenyl group substituted with a phenyl group.

As utilized herein, an alkyl group and an alkylene group may be a linear chain, or a branched chain. As utilized herein, the alkylene group may refer to a alkylene group. The alkyl group and the alkylene group may have each 1 to 60 carbon atoms, 1 to 50 carbon atoms, 1 to 30 carbon atoms, 1 to 20 carbon atoms, 1 to 10 carbon atoms, or 1 to 6 carbon atoms. Examples of the alkyl group include a methyl group, an ethyl group, an n-propyl group, an isopropyl group, an n-butyl group, a s-butyl group, a t-butyl group, a i-butyl group, a 2-ethylbutyl group, 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, a n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyl octyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octa decyl group, an n-nonadecyl group, an n-icosyl group, a 2-ethylicosyl group, a 2-butylicosyl group, a a2-hexylicosyl group, 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but is/are not limited thereto.

As utilized herein, a cycloalkyl group may refer to a cyclic alkyl group. The cyclic alkyl group has 3 to 50 carbon atoms, 3 to 30 carbon atoms, 3 to 20 carbon atoms, or 3 to 10 carbon atoms. Examples of the cycloalkyl group include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc. However, an embodiment of the present disclosure is not limited thereto. As utilized herein, the cycloalkylene group may refer to a divalent cycloalkyl group.

As utilized herein, a heterocycloalkyl group may refer to a cyclic heteroalkyl group including at least one selected from among B, O, N, P, Si and S as a ring-forming atom. The heterocycloalkyl group has 2 to 50 carbon atoms, 2 to 30 carbon atoms, 2 to 20 carbon atoms, or 2 to 10 carbon atoms. Examples of the heterocycloalkyl group include a tetrahydrofuranyl group, a tetrahydropyranyl group, a tetrahydrothiophenyl group, a 1,2,3,4-oxatriazolidinyl group, and/or the like, but are not limited thereto. As utilized herein, the heterocycloalkylene group may refer to a divalent heterocycloalkyl group.

As utilized herein, an aryl group may refer to any functional group or any substituent derived from an aromatic hydrocarbon ring. The aryl group may be a monocyclic aryl group, or a polycyclic aryl group. The aryl group has 6 to 30 ring-forming carbon atoms, 6 to 20 ring-forming carbon atoms, or 6 to 15 ring-forming carbon. Examples of the aryl group include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc. However, an embodiment of the present disclosure is not limited thereto.

As utilized herein, a heteroaryl group may include at least one selected from among B, O, N, P, Si, and S as a hetero atom. When the heteroaryl group includes two or more hetero atoms, the two or more hetero atoms may be the same as, or different from each other. The heteroaryl group may be a monocyclic hetero ring group, or a polycyclic hetero ring group. The heteroaryl group may have 2 to 30 ring-forming carbon atoms, 2 to 20 ring-forming carbon atoms, or 2 to 10 ring-forming carbon atoms. Examples of the heteroaryl group include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc. However, an embodiment of the present disclosure is not limited thereto.

As utilized herein, the description of the above-described aryl group may be applied to an arylene group except that the arylene group is a divalent group. The description of the above-described heteroaryl group may be applied to a heteroarylene group except that the heteroarylene group is a divalent group.

As utilized herein, a silyl group may include an alkyl silyl group and an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but is not limited thereto.

As utilized herein, the number of carbon atoms of an amine group is not particularly limited, but the amine group may have 1 to 30 carbon atoms. The amine group may include an alkyl amine group and an aryl amine group. Examples of the amine group include a methylamine group, a dimethylamine group, a phenylamine group, a diphenylamine group, a naphthylamine group, and a 9-methyl-anthracenylamine group, but is/are not limited thereto.

As utilized herein, (meth)arylate may refer to acrylate and methacrylate.

Referring to FIG. 12 again, the electron transport composition ICP according to an embodiment includes an inorganic particle MO and a solvent SV. The inorganic particle MO may be a metal oxide containing zinc (Zn) and a first metal. The inorganic particle MO may be a metal oxide, in which the first metal is doped to a metal oxide containing zinc (Zn). In an embodiment, the first metal may have a larger bond dissociation energy with oxygen than zinc (Zn). In an embodiment, the first metal may be tin (Sn), copper (Cu), or nickel (Ni). The inorganic particle MO may contain the first metal substituted for a zinc (Zn) ion in ZnO. Therefore, the stability may be improved, and excellent or suitable electrical and optical characteristics may be exhibited.

The first metal may be doped to the metal oxide containing zinc (Zn) and may serve to control electron mobility of zinc oxide and to improve stability. Because the inorganic particle MO contains the first metal having the larger bond dissociation energy with oxygen than zinc (Zn), the inorganic particle MO may have the improved stability and lower electron mobility than the ZnO metal oxide, and thus excessive electron injection to the emission layer EML may be suppressed or reduced. Therefore, the luminous efficiency and element lifespan characteristics of the light-emitting element ED may be improved.

The bond dissociation energies between metal elements and an oxygen atom are listed in Table 1. Referring to Table 1, as the first metal, tin (Sn), copper (Cu), or nickel (Ni), which have a higher bonding energy with oxygen than the bond dissociation energy of Zn-O, may be selected. For, example, the first metal may be tin (Sn).

TABLE 1

| | Bond dissociation |
|---|---|
| | energy (kJ/mol) |
| Zn—O | <250 |
| Sn—O | 528 |
| Cu—O | 343 |
| Ni—O | 392 |

In an embodiment, the inorganic particle MO is represented by Formula 1.

Zn₁₋ₓMₓO Formula 1

where, in Formula 1, M is a metal having a larger bond dissociation energy with oxygen than zinc (Zn) above. In an embodiment, M may be tin (Sn), copper (Cu), or nickel (Ni). For example, M may be tin (Sn).

X satisfies 0<x<1. In an embodiment, x may satisfy 0<x<0.2. For example, x may satisfy 0<x≤0.1. When x is 0.2 or more, the electron mobility of the inorganic particle MO is excessively degraded and thus charge balance in the emission layer EML may be disrupted. When x falls within the above-described range in Formula 1, while the stability may be improved, the desired or suitable electron mobility characteristics may be exhibited. Therefore, luminous efficiency and element lifespan characteristics of the light-emitting element ED may be improved.

Characteristics of the quantum-dot-based elements are determined by quantum efficiency of quantum dots QD1, QD2, and QD3 (see FIG. 5), charge carrier balance, light-extracting efficiency, a leakage current, and/or the like. For example, for improving luminous efficiency of the emission layer EML, methods, such as adjusting for excitons to be confinement to the emission layer, adjusting for holes and electrons to be smoothly transported to the quantum dots QD1, QD2, and QD3 (see FIG. 5), or preventing or reducing a leakage current, may be utilized. For achieving this, in the light-emitting element ED including the quantum dots QD1, QD2, and QD3 (see FIG. 5), a method utilizing inorganic metal oxide such as ZnO, ZnMgO in the electron transport region ETR may be utilized. However, when the inorganic metal oxide such as ZnO, ZnMaO is utilized in the electron transport region ETR, the electron mobility from the second electrode EL2 to the emission layer EML may become larger than the hole mobility from the first electrode EL1 to the emission layer EML, and thus a phenomenon in which the electrons, compared to the holes, are excessively injected into the emission layer EML may occur. Accordingly, charge balance in the emission layer EML may be disrupted, and thus luminous efficiency of the light-emitting element ED may be degraded. In some embodiments, the electrons excessively injected may be accumulated in the emission layer EML and in an interlayer interface adjacent to the emission layer EML, which cause deterioration of the interface and lead to lifespan degradation of the light-emitting element ED. In some embodiments, when the composition is manufactured utilizing zinc (Zn)-based metal oxide such as ZnO, ZnMgO, gelation and particle aggregation and/or the like may occur due to low dispersion stability and/or the like of ZnO and ZnMgO. Such phenomena of particle gelation and aggregation may cause difficulties in jetting, forming films, and/or the like during the manufacturing process of elements.

According to the present disclosure, when the electron transport composition ICP forming the electron transport region ETR includes the inorganic particle MO containing zinc (Zn) and the first metal, and thus the stability of the inorganic particle MO may be improved. Because the inorganic particle MO contains zinc (Zn) and the first metal having a larger bond dissociation energy than zinc (Zn), the stability of the inorganic particle MO may be improved, and thus in addition to a formation of a substantially uniform thin-film, electrical and optical characteristics of the light-emitting element may be improved. As a result, when the electron transport region is formed utilizing the electron transport composition ICP according to an embodiment of the present disclosure, emission characteristics and element lifespan characteristics of the display device may be improved. In some embodiments, the electron injection characteristics of the inorganic particle MO are controlled or selected by adjusting contents of zinc and the first metal included in the inorganic particle MO, and thus charge injection balance of the light-emitting element may be improved. For example, the electron injection characteristics of the electron transport region ETR may be controlled or selected by adjusting the contents of zinc (Zn) and the first metal in the inorganic particle MO. As a result, charge injection balance of the light-emitting element ED including the quantum dots QD1, QD2, and QD3 (see FIG. 5) may be further improved, and thus efficiency may be improved and accumulation of the electrons on the interface and/or the like may be prevented or reduced. Therefore, the lifespan of the light-emitting element may be improved.

The electron transport composition ICP according to an embodiment of the present disclosure includes a solvent SV. The solvent SV may include a polyethylene glycol moiety. The solvent SV may include a polyethylene glycol moiety and a first substituent linked to an end of the polyethylene glycol moiety. In an embodiment, the first substituent may be an alkyl group, a cycloalkyl group, a heterocycloalkyl group, a silyl group, an aryl group, or a heteroaryl group. The electron transport composition ICP includes the solvent SV containing the polyethylene glycol moiety and the first substituent, and thus dispersion stability of the inorganic particle MO may be improved. Therefore, solution processibility may be improved. In some embodiments, as utilized herein, the first substituent may refer to a substituent corresponding to R₃ in Formula 2, which will be described later.

In an embodiment, the solvent SV may be represented by Formula 2.

R₁—O—(R₂—O)ₙ—R₃ Formula 2

where, in Formula 2, R₁ is a hydrogen atom, or a deuterium atom. For example, R₁ may be a hydrogen atom.

In Formula 2, R₂ is a substituted or unsubstituted alkylene group having 1 to 60 carbon atoms, a substituted or unsubstituted cycloalkylene group having 3 to 10 ring-forming carbon atoms, a substituted or unsubstituted heterocycloalkylene group having 2 to 10 ring-forming carbon atoms, a substituted or unsubstituted arylene group having 6 to 30 ring-forming carbon atoms, or a substituted or unsubstituted heteroarylene group having 2 to 30 ring-forming carbon atoms. For example, R₂ may be a substituted or unsubstituted alkylene group having 1 to 20 carbon atoms. For example, R₂ may be a substituted or unsubstituted ethylene group, or a substituted or unsubstituted isopropylene group.

In Formula 2, R₃ is a substituted or unsubstituted alkyl group having 1 to 20 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms. In an embodiment, R₃ may be a substituted or unsubstituted alkyl group having 1 to 10 carbon atoms, a substituted or unsubstituted heterocycloalkyl group having 2 to 10 ring-forming carbon atoms, or a substituted or unsubstituted aryl group having 6 to 30 ring-forming carbon atoms. For example, R₃ may be a substituted or unsubstituted methyl group, a substituted unsubstituted ethyl group, a substituted or unsubstituted n-propyl group, a substituted or unsubstituted isopropyl group, a substituted or unsubstituted t-butyl group, a substituted or unsubstituted isopentyl group, a substituted or unsubstituted benzyl group, or a substituted or unsubstituted tetrahydrofuran group.

In Formula 2, n is an integer of 1 to 5. For example, n may be 1 to 3.

In an embodiment, the solvent represented by Formula 2 may be represented by any one selected from among Formulas 3-1 to 3-3.

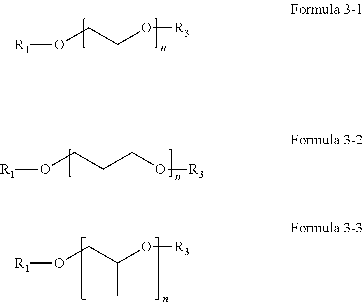

where, in Formulas 3-1 to 3-3, the same descriptions as in Formula 2 above may be applied to R₁, R₃, and n.

In an embodiment, the solvent represented by Formula 2 may be represented by any one selected from among Formulas 4-1 to 4-8.

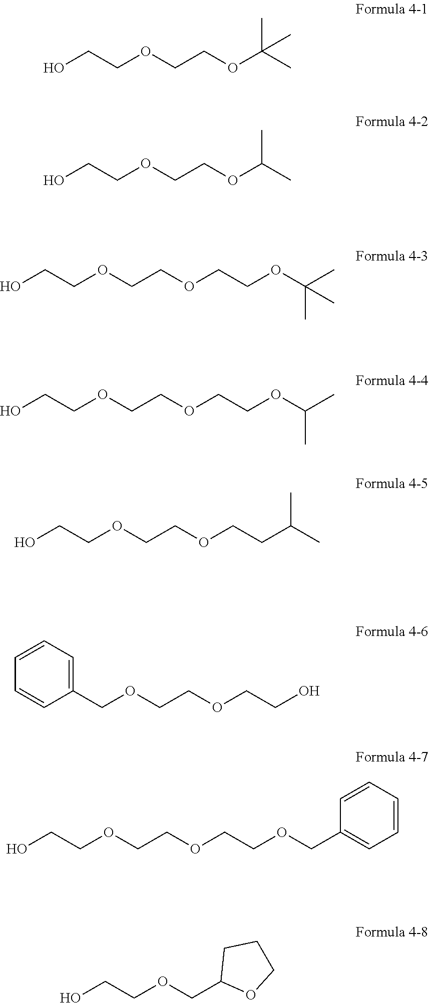

In an embodiment, the electron transport composition ICP may include about 0.1 wt % to about 5.0 wt % of the inorganic particle MO with respect to about 100 wt % of the solvent SV. When the content (e.g., amount) of the inorganic particle MO is less than about 0.1 wt %, an improving effect of the electron injection balance of the light-emitting element may be reduced. When the content (e.g., amount) of the inorganic particle MO exceeds about 5.0 wt %, dispersion state of the inorganic particle MO becomes unstable, and thus particle gelation and aggregation and/or the like may occur in the electron transport composition ICP. As a result, it may be difficult to adjust the thickness uniformity of a thin film. When the content (e.g., amount) of the inorganic particle MO falls within the above-described ranges, the inorganic particle MO in the electron transport composition ICP may have excellent or suitable dispersion stability, and thus a substantially uniform thin film may be formed, and the thin film formed from the electron transport composition ICP may have excellent or suitable charge mobility.

In an embodiment, a boiling point of the solvent SV may be about 200° C. or more. For example, the boiling point of the solvent SV may be about 200° C. to about 500° C. Because the solvent has the high boiling point of about 200° C. or more, when the electron transport composition ICP is applied and then dried, a stain occurrence may decrease, and an occurrence of defects due to the mixing of materials on the interface between adjacent layers may be suppressed or reduced.

In an embodiment, a viscosity of the solvent SV at room temperature (about 25° C.) may be about 30 centipoise (cP or cp) or less. For example, the viscosity of the solvent SV may be about 5 cp to about 20 cp. When the viscosity of the solvent SV falls within the above-described range, the solution processibility of the electron transport composition ICP may be improved and thus thin-film stability of the light-emitting element may be improved.

In an embodiment, surface tension of the solvent SV at room temperature (about 25° C.) may be about 40 dyne per centimeter (dyn/cm) or less. For example, the surface tension of the solvent SV may be about 10 dyn/cm to about 34 dyn/cm. When the surface tension of the solvent SV falls within the above-described range, solution processibility of the electron transport composition ICP may be improved, and thus the thin-film stability of the light-emitting element may be improved.

The electron transport composition ICP according to an embodiment of the present disclosure includes a solvent SV represented by Formula 2, dispersion stability of the inorganic particle MO in the electron transport composition ICP may be improved. In some embodiments, because the solvent SV represented by Formula 2 is utilized in the electron transport composition ICP including the inorganic particle MO, surface stability of the inorganic particle MO may be improved, and thus efficiency and lifespan characteristics of the light-emitting element may be further improved.

In an embodiment, the electron transport composition ICP may further include an additional solvent in addition to the above-described solvent SV. The additional solvent may be an organic solvent or an inorganic solvent such as water. The organic solvent may include an aprotic solvent or a protic solvent.

The aprotic solvent may include, for example, hexane, toluene, chloroform, dimethyl sulfoxide, octane, xylene, hexadecane, cyclohexylbenzene, triethylene glycol monobutyl ether, or dimethyl formamide, decane, dodecane 1-hexadecene, cyclohexylbenzene, tetrahydronaphthalene, ethylnaphthalene, ethylbiphenyl, isopropylnaphthalene, diisopropylnaphthalene, diisopropylbiphenyl, xylene, isopropylbenzene, pentylbenznene, diisopropylbenzene, decahydronaphthalene, phenylnaphthalene, cyclohexyldecahydronaphthalene, decylbenzene, dodecylbenzene, octylbenzene, cyclohexane, cyclopentane, cycloheptane, etc., but is not limited thereto.

The protic solvent may be a compound that may provide at least one proton. More specifically, the protic solvent may be a compound containing at least one dissociable proton. For example, the protic solvent may refer to a protic liquid material, or a protic polymer. The protic solvent may include methanol, ethanol, propanol, isopropanol, ethylene glycol, propylene glycol, diethylene glycol, etc., but is not limited thereto.

In an embodiment, the electron transport composition ICP may further include an additive represented by Formula 5. The additive represented by Formula 3 may be included in the electron transport composition ICP and thus may serve to improve the dispersion stability of the inorganic particle MO with the solvent SV. When the electron transport composition ICP includes the solvent SV represented by Formula 1 and the additive represented by Formula 5, dispersion stability of the inorganic particle MO may be improved, and thus solution processibility may be further improved.

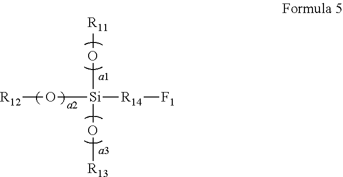

wherein, in Formula 5, R₁₁ to R₁₃ may each independently be a substituted or unsubstituted alkyl group having 1 to 30 carbon atoms, a substituted or unsubstituted cycloalkyl group having 3 to 20 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms. In an embodiment, R₁₁ to R₁₃ may be a substituted or unsubstituted alkyl group having 1 to 10 carbon atoms. For example, R₁₁ to R₁₄ may be a substituted or unsubstituted methyl group, or a substituted or unsubstituted ethyl group.

In Formula 5, R₁₄ may be a substituted or unsubstituted alkylene group having 1 to 30 carbon atoms, a substituted or unsubstituted cycloalkylene group having 3 to 20 ring-forming carbon atoms, a substituted or unsubstituted arylene group having 6 to 30 ring-forming carbon atoms, or a substituted or unsubstituted heteroarylene group having 2 to 30 ring-forming carbon atoms. In an embodiment, R₁₄ may be a substituted or unsubstituted alkylene group having 1 to 10 carbon atoms.

In Formula 5, a1 to a3 may each independently be 0 or 1. In an embodiment, at least one selected from among a1 to a3 may be 1. For example, at least one selected from among a1 to a3 may be 1, and the rest may be 0. In some embodiments, all a1 to a3 may (each) be 1.

In Formula 5, F₁ may be a substituted or unsubstituted (meth)acrylate group, or a substituted or unsubstituted epoxy group, or a substituted or unsubstituted amine group. For example, F₁ may be a substituted or unsubstituted (meth)acrylate group.

In an embodiment, the additive represented by Formula 5 may be represented by any one selected from among Formulas 6-1 to 6-5.

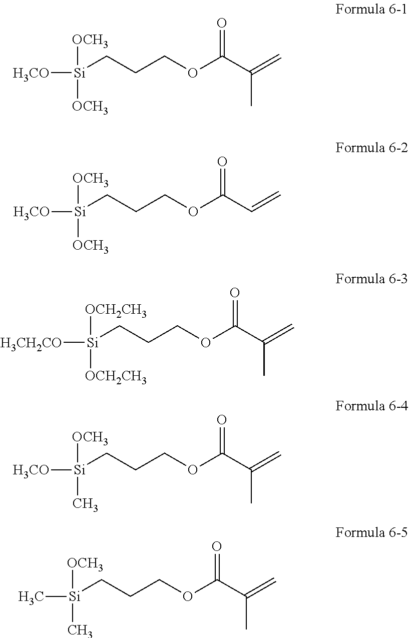

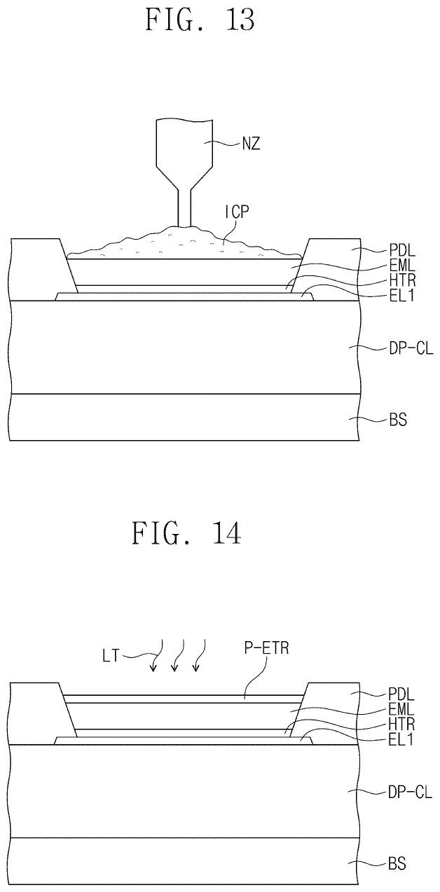

FIG. 13 schematically shows the providing of a preliminary electron transport region (S302) among operations for manufacturing the light-emitting element according to an embodiment. The providing of the preliminary electron transport region (S302) may be the applying of the electron transport composition ICP onto the emission layer EML.

In an embodiment, the method for applying the electron transport composition ICP onto the emission layer EML is not particularly limited, and methods such as a spin coating method, a casting method, the Langmuir-Blodgett (LB) method, an inkjet printing method, a laser printing method, and/or a laser induced thermal imaging (LITI) may be utilized. In FIG. 13, the electron transport composition ICP is applied between the pixel-defining films PDLs through a nozzle NZ, but is not limited thereto.

FIG. 14 schematically shows, in the method for manufacturing a light-emitting element according to an embodiment, the performing a heat treatment of the preliminary electron transport region at a first temperature (S303). The performing a heat treatment of the preliminary electron transport region (S303) may be the performing a heat treatment of a preliminary electron transport region P-ETR by providing heat LT for a set or predetermined time at a first temperature.

The solvent SV (see FIG. 12) may be removed through the performing a heat treatment at the first temperature (S303), and accordingly, the substantially uniform thin film may be formed. In an embodiment, the first temperature is not particularly limited, and may be about 50° C. to about 150° C. However, an embodiment of the present disclosure is not limited thereto, and the temperature and the time for the performing a heat treatment at the first temperature may be suitably selected depending on the types (kinds) and amounts of materials.

In some embodiments, FIGS. 13 and 14 illustrate that the hole transport region HTR and the electron transport region ETR are each provided between the pixel-defining films PDLs, but an embodiment of the present disclosure is not limited thereto. The hole transport region HTR and the electron transport region ETR may be each provided as a common layer to overlap the pixel-defining film PDL.

Most inorganic metal oxides have many defects such as metal vacancy, oxygen vacancy and surface defects, and due to such defects, a defect energy level may be formed. There are limitations in that the defect energy level may cause charge loss in the element and may affect emission quenching characteristics of the emission layer including the quantum dot, and thus efficiency and lifetime characteristics of the light-emitting element may be reduced. In some embodiments, there is a limitation in that atomic bonding in the inorganic metal oxide is weak, and thus the characteristic change, according to the driving of element, is severe. In some embodiments, when an ink is manufactured by nanoparticles for manufacturing the light-emitting element, there are limitations in that gelation or aggregation of the particles may occur due to exposure to oxidation and moisture, or aggregation may be induced due to a short distance between the particles, and/or the like. The phenomenon of gelation and aggregation may cause defects in jetting, forming films, and/or the like during a preparing process of a panel.

According to the present disclosure, because the electron transport composition ICP forming the electron transport region includes the inorganic particle MO containing zinc (Zn) and the first metal, stability of the inorganic particle MO may be improved. The inorganic particle MO contains zinc (Zn) and a first metal having the higher bond dissociation energy than zinc (Zn), stability of the inorganic particle MO may be improved, and thus, in addition to the substantially uniform thin film formation, electrical and optical characteristics of the light-emitting element may be improved. As a result, when the electron transport region is formed utilizing the electron transport composition ICP according to an embodiment of the present disclosure, the display device may have improved emission characteristics and element lifespan characteristics. In some embodiments, the electron injection characteristics of the inorganic particle MO may be controlled or selected by adjusting the contents of zinc (Zn) and the first metal included in the inorganic particle MO, and thus the charge injection balance of the light-emitting element may be improved. Therefore, when the electron transport region is formed by applying the electron transport composition according to an embodiment, a current density in the element may increase, and thus ultimately luminous efficiency and lifespan of the display device may be improved.

Hereinafter, with reference to Examples and Comparative Examples, a nitrogen-containing compound according to an embodiment of the present disclosure and a light-emitting element according to an embodiment will be specifically described. In some embodiments, Examples shown are only for the understanding of the present disclosure, and the scope of the present disclosure is not limited thereto.

### EXAMPLES

### 1. Synthesis of an Inorganic Particle

### Synthesis Example 1: Zn_{0.9}Sn²⁺_{0.1}O Inorganic Particle

About 72 mmol of zinc acetate dihydrate, about 8 mmol of tin (II) acetate, and about 320 mL of dimethyl sulfoxide were injected into a reactor and then the mixture was stirred for about 120 minutes. Then, a temperature of the reactor was set to about 30° C., and then about 80 mL of a mixture solution of 1 M of tetramethylammonium hydroxide pentahydrate (TMAH) and ethanol was injected for about 20 minutes. After the injection of TMAH solution was completed, the reaction was maintained for about 2 hours, and then the synthesized Zn_{0.9}Sn²⁺_{0.1}O inorganic particle was deposited utilizing acetone and hexane and then dispersed into the ink.

### Synthesis Example 2: Zn_{0.8}Sn²⁺_{0.2}O Inorganic Particle

About 64 mmol of zinc acetate dihydrate, about 16 mmol of tin (II) acetate, and about 320 mL of dimethyl sulfoxide were injected into a reactor and then the mixture was stirred for about 120 minutes. Then, a temperature of the reactor was set to about 30° C., and then about 80 mL of a mixture solution of 1 M of tetramethylammonium hydroxide pentahydrate (TMAH) and ethanol was injected for about 20 minutes. After the injection of TMAH solution was completed, the reaction was maintained for about 2 hours, and then the synthesized Zn_{0.8}Sn²⁺_{0.2}O inorganic particle was deposited utilizing acetone and hexane and then dispersed into the ink.

### Synthesis Example 3: ZnO Inorganic Particle

About 80 mmol of zinc acetate dihydrate, and about 320 mL of dimethyl sulfoxide were injected into a reactor and then the mixture was stirred for about 120 minutes. Then, a temperature of the reactor was lowered to about 4° C., and then about 80 mL of a mixture solution of 1 M of tetramethylammonium hydroxide pentahydrate (TMAH) and ethanol was injected for about 20 minutes. After the injection of the TMAH solution was completed, the reaction was maintained for about 1 hour and 20 minutes, and then the synthesized ZnO nanoparticle was deposited utilizing acetone and then dispersed into the ink.

### Synthesis Example 4: ZnMgO Inorganic Particle

About 65.2 mmol of zinc acetate dihydrate, and about 14.8 mmol of magnesium acetate tetrahydrate were dissolved in about 320 mL of dimethyl sulfoxide (DMSO), and then temperature of the reactor was lowered to about 4° C., and then about 80 mL of a mixture solution of 1 M of tetramethylammonium hydroxide pentahydrate (TMAH) and ethanol was injected for about 20 minutes. After the injection of the TMAH solution was completed, the reaction was maintained for about 1 hours and 20 minutes, and then the synthesized ZnO nanoparticle was deposited utilizing acetone and hexane and then dispersed into the ink.

### Evaluation of Solvent Properties

A boiling point, a velocity, and surface tension of the solvent represented by Compounds 1-1 to 1-8 were measured and the measurement results were listed in Table 2. Herein, the velocity was measured utilizing the viscometer DV-2+ made by Brookfield Viscometers Ltd, and the surface tension was measured utilizing DST-60 made by SEO Co., Ltd.

TABLE 2

| | b.p. | Viscosity | Surface tension |
|---|---|---|---|
| Solvent | (° C.) | (cp) | (dyn/cm) |
| Compound 4-1 | 224 | 6.2 | 28.2 |
| Compound 4-2 | 220 | 6.0 | 28.0 |
| Compound 4-3 | 271 | 7.8 | 30.9 |
| Compound 4-4 | 264 | 7.6 | 30.6 |
| Compound 4-5 | 245 | 6.5 | 29.2 |
| Compound 4-6 | 311 | 10.2 | 38.6 |
| Compound 4-7 | 460 | 15.4 | 38.5 |
| Compound 4-8 | 256 | 8.5 | 37.4 |

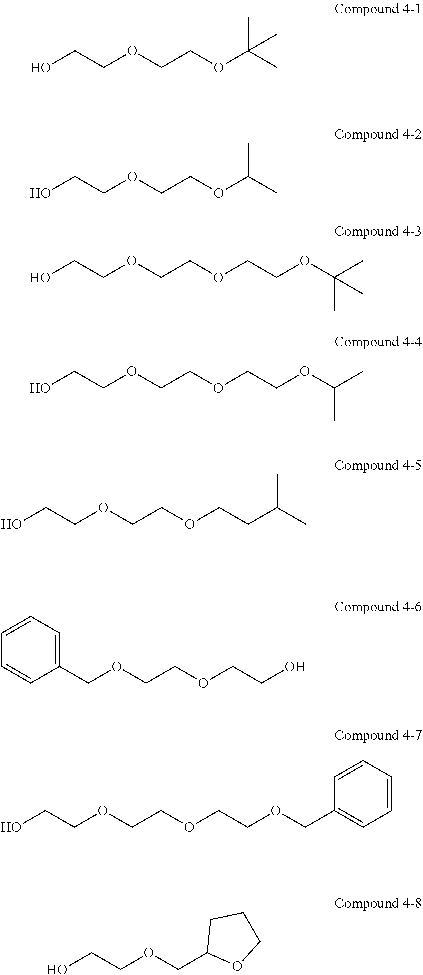

### Manufacture of Electron Transport Composition

As shown in Table 3, electron transport compositions 1 to 5, including an inorganic particle, a solvent, and an additive, and Comparative Example Compositions 1 to 5 were manufactured.

TABLE 3

| | | | | Inorganic | |
|---|---|---|---|---|---|
| | | | | particle | Additive |
| | | | | content | content |
| | | | | (e.g., | (e.g., |
| | | | | amount) | amount) |
| Electron | | | | (Weight | (Weight |
| transport | | | | ratio with | ratio with |
| com- | Inorganic | | | respect to | respect to |
| position | particle | Solvent | Additive | solvent) | oxide) |
| Com- | Zn_{0.9}Sn²⁺_{0.1}O | Compound | — | 3 wt % | — |
| position 1 | | 4-1 | | | |
| Com- | Zn_{0.9}Sn²⁺_{0.1}O | Compound | Compound | 3 wt % | 5 wt % |
| position 2 | | 4-1 | 6-1 | | |
| Com- | Zn_{0.9}Sn²⁺_{0.1}O | Compound | Compound | 3 wt % | 10 wt % |
| position 3 | | 4-1 | 6-1 | | |
| Com- | Zn_{0.9}Sn²⁺_{0.1}O | Compound | Compound | 3 wt % | 15 wt % |
| position 4 | | 4-1 | 6-1 | | |
| Com | Zn_{0.9}Sn²⁺_{0.1}O | Compound | Compound | 3 wt % | 20 wt % |
| position 5 | | 4-1 | 6-1 | | |
| Com- | Zn_{0.8}Sn²⁺_{0.2}O | Compound | Compound | 3 wt % | 20 wt % |
| parative | | 4-1 | 6-1 | | |
| com- | | | | | |
| position 1 | | | | | |
| Com- | ZnO | Compound | — | 3 wt % | — |
| parative | | 4-1 | | | |
| com- | | | | | |
| position 2 | | | | | |
| Com | ZnO | Compound | Compound | 3 wt % | 20 wt % |
| parative | | 4-1 | 6-1 | | |
| com- | | | | | |
| position 3 | | | | | |
| Com- | ZnMgO | Compound | — | 3 wt % | — |
| parative | | 4-1 | | | |
| com- | | | | | |
| position 4 | | | | | |
| Com- | ZnMgO | Compound | Compound | 3 wt % | 20 wt % |
| parative | | 4-1 | 6-1 | | |
| com- | | | | | |
| position 5 | | | | | |

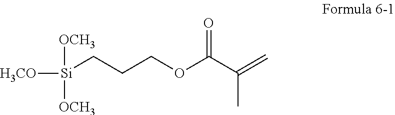 [SMILES: C=C(C)C(=O)OCCC[Si](OC)(OC)OC]

### Evaluation 1 of Electron Transport Composition

After 1 week and 2 weeks from being left at room temperature, the particle size of each of the electron transport compositions (each being in a form of particles) was measured, and the result was listed in Table 4. In Table 4, the particle size was measured utilizing a DLS instrument (Nano-ZS90 made by Malvern Panalytical Ltd). As a difference between an initial average particle size and an average particle size after 1 week, and a difference between the initial average particle size and an average particle size after 2 weeks are smaller, the dispersion stability of the inorganic particle to the solvent is excellent or suitable.

TABLE 4

| | | | Average | Average |
|---|---|---|---|---|
| | | Initial | particle | particle |
| | | average | size | size |
| | Electron | particle | after | after |
| | transport | size | 1 week | 2 weeks |
| Classification | composition | (nm) | (nm) | (nm) |
| Example 1-1 | Composition 1 | 12 | 12 | 58 |
| Example 1-2 | Composition 2 | 11 | 11 | 28 |
| Example 1-3 | Composition 3 | 12 | 11 | 25 |
| Example 1-4 | Composition 4 | 13 | 13 | 12 |
| Example 1-5 | Composition 5 | 12 | 13 | 13 |
| Comparative | Comparative | 11 | 13 | 12 |
| Example 1-1 | Composition 1 | | | |
| Comparative | Comparative | 10 | 450 | — |
| Example 1-2 | Composition 2 | | | |
| Comparative | Comparative | 11 | 270 | — |
| Example 1-3 | Composition 3 | | | |
| Comparative | Comparative | 12 | 380 | — |
| Example 1-4 | Composition 4 | | | |
| Comparative | Comparative | 10 | 120 | — |
| Example 1-5 | Composition 5 | | | |

Referring to Table 4 above, it can be confirmed that the compositions according to Examples 1-1 to 1-5 and Comparative Example 1-1 each have a smaller difference between the initial average particle size and the average particle size after 1 week than the compositions according to Comparative Examples 1-1 and 1-2. In some embodiments, it can be seen that, in the cases of the compositions according to Examples 1-1 to 1-5 and Comparative Example 1-1, even after 2 weeks, the average particle sizes do not have significant changes in the average particle sizes. In contrast, it can be confirmed that the compositions according to Comparative Examples 1-2 to 1-5 have excessively large average particle sizes after two weeks, making it impossible to measure. Therefore, it can be confirmed that Compositions 1 to 5 and Comparative Composition 1, each including the inorganic particle, which contains zinc (Zn) and the first metal, have excellent or suitable dispersity of the inorganic particle. In some embodiments, when the composition according to Examples 1-1 is compared with the compositions according to Examples 1-2 to 1-5, it can be confirmed that the electron compositions according to Examples 1-2 to 1-5, which includes the additive, have a smaller difference between the average particle sizes after 1 week and after 2 weeks than the composition according to Example 1-1, which includes no additive. As a result, in the case of the electron transport composition containing the additive, the dispersion stability of the inorganic particle may be improved and thus the solution processibility may be expected to be further improved.

### (Evaluation 2 of Electron Transport Composition)

Each of the electron transport compositions was jetted from an inkjet equipment, then the jetting was measured after about 24 hours, and the results were listed in Table 5. The jetting criterion is an about ±20 μm of deposition accuracy, and the Dimatix Materials Printer DMP-2850 was utilized as the inkjet equipment.

TABLE 5

| | Electron | | Jetting |
|---|---|---|---|
| | transport | Initial | after 24 |
| Classification | composition | jetting | hours |
| Example 1-1 | Composition 1 | ◯ | ◯ |
| Example 1-2 | Composition 2 | | |
| Example 1-3 | Composition 3 | ◯ | ◯ |
| Example 1-4 | Composition 4 | ◯ | ◯ |
| Example 1-5 | Composition 5 | ◯ | ◯ |
| Comparative | Comparative | ◯ | ◯ |
| Example 1-1 | Composition 1 | | |
| Comparative | Comparative | ◯ | X |
| Example 1-2 | Composition 2 | | |
| Comparative | Comparative | ◯ | X |
| Example 1-3 | Composition 3 | | |
| Comparative | Comparative | ◯ | X |
| Example 1-4 | Composition 4 | | |
| Comparative | Comparative | ◯ | X |
| Example 1-5 | Composition 5 | | |

Referring to Table 5 above, it can be confirmed that the compositions according to Examples 1-1 to 1-5 and Comparative Example 1-1 maintain good or suitable jetting compared to the compositions according to Comparative Examples 1-2 to 1-5, even after being left for about 24 hours. Therefore, it can be confirmed that Compositions 1 to 5, and Comparative Composition 1 include the inorganic particle, which contains zinc (Zn) and the first metal, and thus have improved storage stability and jetting.

### Manufacture of Example 2-1

An ITO glass substrate (50×50 nm, 15 Ω/cm²), which is a glass (product of Samsung-Corning) for EL-QD, was subjected to ultrasonic washing sequentially utilizing pure water and isopropyl alcohol, and then performing ultraviolet (UV) ozone cleansing for about 30 minutes. After cleansing, on the glass substrate, on which a transparent electrode wires were attached, PEDOT:PSS (Clevios™ HIL8) was spin-coated to form a film having a thickness of about 60 nm, and then was baked at about 120° C. for about 10 minutes to form a hole injection layer. Compound 101 was spin-coated on the hole injection layer to form a film having a thickness of about 20 nm, and then was baked for about 10 minutes at about 120° C. to form a hole transport layer.

Red InP quantum dot (QD) was spin-coated on the hole transport layer to form a film having a thickness of about 20 nm, and then was baked for about 10 minutes at about 100° C. to form a red emission layer. Inorganic nanoparticles of Composition 1 were spin-coated on the red emission layer to form a film having a thickness of about 30 nm, and then were baked at about 120° C. for about 10 minutes to form an electron transport layer. The glass substrate was mounted on a substrate holder of a vacuum deposition equipment, and then Al was deposited on the electron transport layer to form an anode having a thickness of about 100 nm, thereby preparing a quantum dot light-emitting element. The equipment utilized in the deposition was Sunicel plus 200 evaporation equipment made by Sunic System.

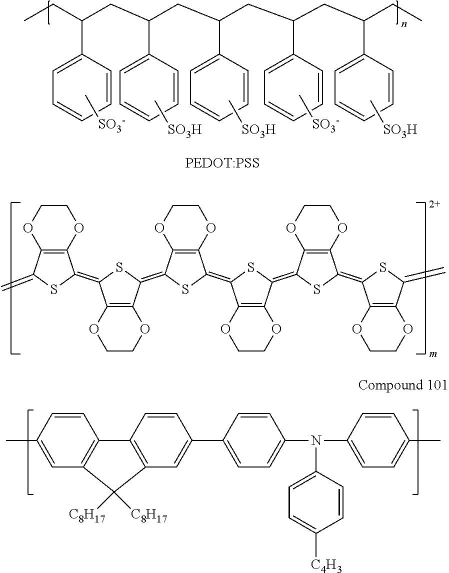

### Manufacture of Light-Emitting Elements According to Examples 2-2 to 2-5 and Comparative Examples 2-1 to 2-5.

The light-emitting elements were prepared in substantially the same manner as Example 2-1 except that the electron transport layers were configured as listed in Table 6.

TABLE 6

| | Electron |
|---|---|
| | transport layer |
| Example 2-1 | Composition 1 |
| Example 2-2 | Composition 2 |
| Example 2-3 | Composition 3 |
| Example 2-4 | Composition 4 |
| Example 2-5 | Composition 5 |
| Comparative | Comparative |
| Example 2-1 | Composition 1 |
| Comparative | Comparative |
| Example 2-2 | Composition 2 |
| Comparative | Comparative |
| Example 2-3 | Composition 3 |
| Comparative | Comparative |
| Example 2-4 | Composition 4 |
| Comparative | Comparative |
| Example 2-5 | Composition 5 |

### Evaluation of Light-Emitting Element

A driving voltage, efficiency, and color coordinate of the quantum dot light-emitting elements prepared according to Examples 2-1 to 2-5 and Comparative Examples 2-1 to 2-5 were measured utilizing methods and the measurement results were listed in Table 7.
Color coordinate: Power was supplied from the current-voltage meter (Keithley SMU 236), and the color coordinate was measured utilizing the luminance meter PR650.
Driving voltage: Power was supplied from the current-voltage meter (Keithley SMU 236), and the luminance was measured utilizing the luminance meter PR650.
Efficiency: Power was supplied from the current-voltage meter (Keithley SMU 236), and the efficiency was measured utilizing the luminance meter PR650.

In some embodiments, the lifespan T90 refers to the time (hr) taken for the luminance to decrease to about 90% of an initial luminance (at about 10 mA/cm²) from about 100%.

TABLE 7

| | Driving | | | | T90 |
|---|---|---|---|---|---|
| | voltage | Efficiency | Color coordinate | | lifespan |
| | [V] | [cd/A] | CIEx | CIEy | [hr] |
| Example | 5.1 | 26.8 | 0.68 | 0.32 | 550 |
| 2-1 | | | | | |
| Example | 5.2 | 23.4 | 0.68 | 0.32 | 520 |
| 2-2 | | | | | |
| Example | 5.1 | 25.6 | 0.68 | 0.32 | 530 |
| 2-3 | | | | | |
| Example | 5.0 | 28.7 | 0.68 | 0.32 | 540 |
| 2-4 | | | | | |
| Example | 5.2 | 29.5 | 0.68 | 0.32 | 550 |
| 2-5 | | | | | |
| Com- | 6.0 | 12.2 | 0.68 | 0.32 | 150 |
| parative | | | | | |
| Example | | | | | |
| 2-1 | | | | | |
| Com- | 4.2 | 11.2 | 0.68 | 0.32 | 120 |
| parative | | | | | |
| Example | | | | | |
| 2-2 | | | | | |
| Com- | 4.4 | 9.2 | 0.68 | 0.32 | 110 |
| parative | | | | | |
| Example | | | | | |
| 2-3 | | | | | |
| Com- | 4.4 | 13.7 | 0.68 | 0.32 | 160 |
| parative | | | | | |
| Example | | | | | |
| 2-4 | | | | | |
| Com- | 4.5 | 15.4 | 0.68 | 0.32 | 170 |
| parative | | | | | |
| Example | | | | | |
| 2-5 | | | | | |

Referring to FIG. 7, it can be seen that the light-emitting elements according to Examples 2-1 to 2-5 have improved luminous efficiency and lifespan characteristics, compared to Comparative Examples 2-1 to 2-5. Referring together to Tables 4, 5, and 7 above, the light-emitting element according to Comparative Examples 2-1, utilizing Comparative Composition 1 has improved dispersion stability and jetting stability because the inorganic particle containing zinc (Zn) and the first metal is utilized. However, because an element ratio of the first metal in the inorganic particle is about 0.2 or more, electron mobility of the inorganic particle is excessively lowered, and thus charge balance in the emission layer is disrupted. Therefore, luminous efficiency and element lifespan decrease, compared to the light-emitting elements according to Examples 2-1 to 2-5. In contrast, it can be confirmed that the light-emitting elements according to Examples 2-1 to 2-5, utilizing Compositions 1 to 5, respectively, have excellent or suitable luminous efficiency and improved element lifespan characteristics while exhibiting excellent or suitable dispersion stability and jetting stability.

In the present disclosure, the electron transport composition ICP forming the electron transport region includes an inorganic particle MO represented by Formula 1 and a solvent SV represented by Formula 2, and thus a metal oxide may have improved dispersion stability. Therefore, in addition to a formation of a substantially uniform thin film, charge balance of the elements may be adjusted through an electron injection control. As a result, when the electron transport region is formed utilizing the electron transport composition ICP according to an embodiment of the present disclosure, the display device may have improved emission characteristics and element lifespan characteristics.

An embodiment may provide the electron transport composition having improved dispersion stability and the light-emitting element having improved luminous efficiency and lifespan characteristics.

An embodiment may provide a method for manufacturing the light-emitting element having improved processibility during the formation process of the electron transport region.

In the present disclosure, singular expressions may include plural expressions unless the context clearly indicates otherwise. It will be further understood that the terms “comprise(s),” “include(s),” or “have/has” when utilized in the present disclosure, specify the presence of stated features, integers, steps, operations, elements, and/or components, but do not preclude the presence or addition of one or more other features, integers, steps, operations, elements, components, and/or groups thereof. The “/” utilized herein may be interpreted as “and” or as “or” depending on the situation.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, when particles (e.g., quantum dot particles or quantum dots) are spherical, “size” indicates a particle diameter or an average particle diameter, and when the particles are non-spherical, the “size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In present disclosure, “not include a or any ‘component’” “exclude a or any ‘component’”, “‘component’-free”, and/or the like refers to that the “component” not being added, selected, or utilized as a component in a compound/composition, but the “component” of less than a suitable amount may still be included due to other impurities and/or external factors in a composition.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

As utilized herein, the term “and/or” includes any and all combinations of one or more of the associated listed items. Throughout the disclosure, the expression “at least one of a, b or c”, “at least one of a-c”, “at least one of a to c”, “at least one of a, b, and/or c”, “at least one among a to c”, etc., indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

The light-emitting device, the display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to a preferred embodiment of the present disclosure, it will be understood that the present disclosure should not be limited to these preferred embodiments, but one or more suitable changes and modifications can be made by those skilled in the art without departing from the spirit and scope of the present disclosure. Accordingly, the technical scope of the present disclosure is not intended to be limited to the contents set forth in the detailed description of the specification, but is intended to be defined by the appended claims, and equivalents thereof.

What is claimed is:

1. An electron transport composition comprising:
an inorganic particle represented by Formula 1; and
a solvent represented by Formula 2:
Zn₁₋ₓMₓO Formula 1
wherein, in Formula 1,
M is Sn, Cu or Ni, and
X satisfies 0<x<1,
R₁—O—(R₂—O)ₙ—R₃ Formula 2
wherein, in Formula 2,
R₁ is a hydrogen atom, or a deuterium atom,
R₂ is a substituted or unsubstituted alkylene group having 1 to 60 carbon atoms, a substituted or unsubstituted cycloalkylene group having 3 to 10 ring-forming carbon atoms, a substituted or unsubstituted heterocycloalkylene group having 2 to 10 ring-forming carbon atoms, a substituted or unsubstituted arylene group having 6 to 30 ring-forming carbon atoms, or a substituted or unsubstituted heteroarylene group having 2 to 30 ring-forming carbon atoms,
R₃ is a substituted or unsubstituted alkyl group having 1 to 20 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms, and
n is an integer of 1 to 5.

2. The electron transport composition of claim 1, wherein M is Sn.

3. The electron transport composition of claim 1, wherein x satisfies 0<x<0.2.

4. The electron transport composition of claim 1, wherein the solvent represented by Formula 2 is represented by any one selected from among Formulas 3-1 to 3-3: 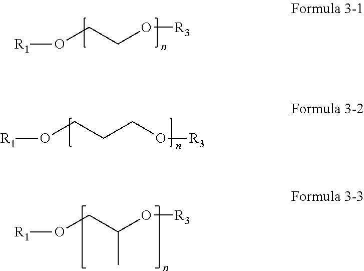
wherein, in Formulas 3-1 to 3-3,
R₁, R₃, and n are the same as defined in Formula 2.

5. The electron transport composition of claim 1, wherein a boiling point of the solvent is about 200° C. or more.

6. The electron transport composition of claim 1, wherein a viscosity of the solvent is about 30 centipoise (cP or cp) or less and a surface tension of about 40 dyne per centimeter (dyn/cm) or less.

7. The electron transport composition of claim 1, wherein viscosity of the solvent is about 20 centipoise (cP or cp) or less, and surface tension is about 34 dyne per centimeter (dyn/cm) or less.

8. The electron transport composition of claim 1, wherein the solvent represented by Formula 2 is represented by any one selected from among Formulas 4-1 to 4-8:

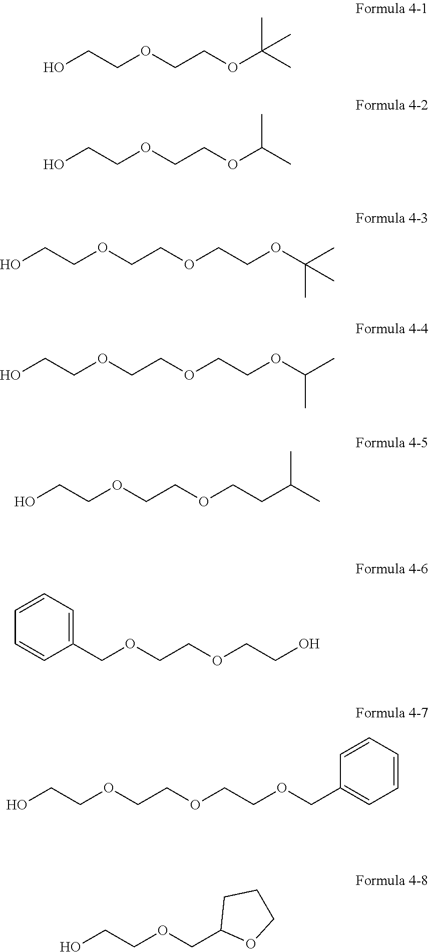

9. The electron transport composition of claim 1 further comprising, an additive represented by Formula 5: 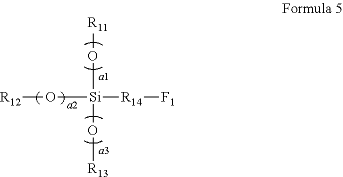
wherein, in Formula 5,
R₁₁ to R₁₃ are each independently a substituted or unsubstituted alkyl group having 1 to 30 carbon atoms, a substituted or unsubstituted cycloalkyl group having 3 to 20 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms,
R₁₄ is a substituted or unsubstituted alkylene group having 1 to 30 carbon atoms, a substituted or unsubstituted cycloalkylene group having 3 to 20 ring-forming carbon atoms, a substituted or unsubstituted arylene group having 6 to 30 ring-forming carbon atoms, or a substituted or unsubstituted heteroarylene group having 2 to 30 ring-forming carbon atoms,
a1 to a3 are each independently 0 or 1,
at least one selected from among a1 to a3 is 1, and
F₁ is a substituted or unsubstituted (meth)acrylate group, or a substituted or unsubstituted epoxy group, or a substituted or unsubstituted amine group.

10. The electron transport composition of claim 9, wherein the additive represented by Formula 5 is represented by any one selected from among Formulas 6-1 to 6-5:

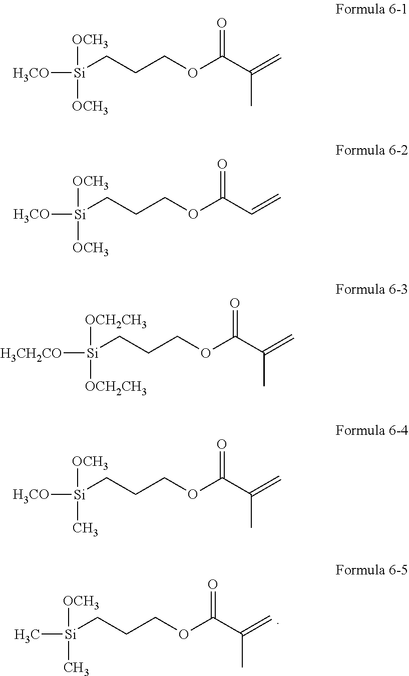

11. A method for manufacturing a light-emitting element, the method comprising:
applying a hole transport region on a first electrode;
applying an emission layer on the hole transport region;
applying an electron transport region on the emission layer; and
applying a second electrode on the electron transport region,
wherein, the applying of the electron transport region comprises:
preparing an electron transport composition comprising inorganic particles and a solvent;
applying a preliminary electron transport region by applying the electron transport composition onto the emission layer; and
performing a heat treatment of the preliminary electron transport region at a first temperature,
the inorganic particles are represented by Formula 1, and
the solvent is represented by Formula 2:
Zn₁₋ₓMₓO Formula 1
wherein, in Formula 1,
M is Sn, Cu, or Ni, and
X satisfies 0<x<1,
R₁—O—(R₂—O)ₙ—R₃ Formula 2
wherein, in Formula 2,
R₁ is a hydrogen atom, or a deuterium atom,
R₂ is a substituted or unsubstituted alkylene group having 1 to 60 carbon atoms, a substituted or unsubstituted cycloalkylene group having 3 to 10 ring-forming carbon atoms, a substituted or unsubstituted heterocycloalkylene group having 2 to 10 ring-forming carbon atoms, a substituted or unsubstituted arylene group having 6 to 30 ring-forming carbon atoms, or a substituted or unsubstituted heteroarylene group having 2 to 30 ring-forming carbon atoms,
R₃ is a substituted or unsubstituted alkyl group having 1 to 60 carbon atoms, a substituted or unsubstituted cycloalkyl group having 3 to 10 ring-forming carbon atoms, a substituted or unsubstituted heterocycloalkyl group having 2 to 10 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms, and
n is an integer of 1 to 5.

12. The method of claim 11, wherein the first temperature is about 50° C. to about 150° C.

13. The method of claim 11, wherein M is Sn.

14. The method of claim 11, wherein x satisfies 0<x<0.2.

15. The method of claim 11, the electron transport composition comprises the inorganic particles of about 0.1 wt % to about 5.0 wt % with respect to the solvent 100 wt %.

16. The method of claim 11, wherein the electron transport composition further comprises an additive represented by Formula 5: 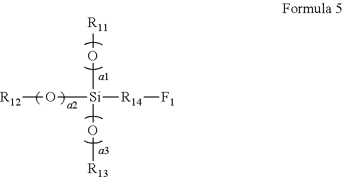
wherein, in Formula 5,
R₁₁ to R₁₃ are each independently a substituted or unsubstituted alkyl group having 1 to 30 carbon atoms, a substituted or unsubstituted cycloalkyl group having 3 to 20 ring-forming carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms,
R₁₄ is a substituted or unsubstituted alkylene group having 1 to 30 carbon atoms, a substituted or unsubstituted cycloalkylene group having 3 to 20 ring-forming carbon atoms, a substituted or unsubstituted arylene group having 6 to 30 ring-forming carbon atoms, or a substituted or unsubstituted heteroarylene group having 2 to 30 ring-forming carbon atoms,
a1 to a3 are each independently 0 or 1,
at least one selected from among a1 to a3 is 1, and
F₁ is a substituted or unsubstituted (meth)acrylate group, a substituted or unsubstituted epoxy group, or a substituted or unsubstituted amine group.

17. A light-emitting element comprising:
a first electrode;
a hole transport region on the first electrode;
an emission layer on the hole transport region;
an electron transport region on the emission layer; and
a second electrode on the electron transport region,
wherein the electron transport region comprises an inorganic particle represented by Formula 1:
Zn₁₋ₓMₓO Formula 1
where, in Formula 1,
M is Sn, Cu, or Ni, and
x satisfies 0<x<0.2.

18. The light-emitting element of claim 17, wherein the emission layer comprises quantum dots.

19. The light-emitting element of claim 18, wherein each of the quantum dots comprises a core and a shell around the core.

20. The light-emitting element of claim 17, wherein M is Sn.
